(19) United States
(12) Patent Application Publication
(10) Pub. No.: US 2026/0150482 A1
(43) Pub. Date: May 28, 2026

(54) LAST-STEP INTERCONNECTION FOR PEROVSKITE MODULES

(71) Applicant: Tandem PV, Fremont, CA (US)

(72) Inventors: Colin David BAILIE, Morgan Hill, CA (US); Chris EBERSPACHER, Palo Alto, CA (US)

(21) Appl. No.: 19/401,268

(22) Filed: Nov. 25, 2025

Related U.S. Application Data
(60) Provisional application No. 63/725,530, filed on Nov. 26, 2024.

(51) Int. Cl. H10K 39/18; H10K 39/12

(52) U.S. Cl. CPC H10K 39/18; H10K 39/12

(57) ABSTRACT

Embodiments of the disclosure include a photovoltaic (PV) device comprising:
a plurality of PV cells coupled in series, wherein the plurality PV cells comprise: a first contact layer; a semiconductor layer disposed over the first contact layer; and a second contact layer disposed over the semiconductor layer; a feature scribe that extends between a first PV cell and a second PV cell of the plurality of PV cells, the feature scribe exposing at least a portion of the first contact layer of the first PV cell and the second PV cell; and an insulating layer that covers at least a leading edge of the feature scribe and an exposed portion of the first contact layer of the first PV cell that is exposed in the feature scribe.

### CROSS-REFERENCE TO RELATED APPLICATIONS

This application claims the benefit of U.S. provisional patent application Ser. No. 63/725,530, filed Nov. 26, 2024, which is herein incorporated by reference.

### BACKGROUND

### Field

Embodiments of the present disclosure generally relate to solar cells and methods of manufacturing thereof.

### Description of the Related Art

Perovskite photovoltaic solar devices, also generally referred to as PV devices, include a plurality of perovskite photovoltaic cells (PV cells) coupled in series. PV devices have attracted attention in the solar cell industry for their high conversion efficiencies. Yet for commercialization of the technology, the process of generating PV devices needs to be streamlined to reduce the cost and time it takes to manufacture the overall PV device.

Currently PV cell manufacturing processes require many operations and tools. For example, manufacturing a PV device can include about 13 to about 18 operations and/or tools. The quantity of operations and tools is due to the multiple scribes, which require the PV device to be moved in/out of and separately oriented and aligned within multiple different processing tools and processing systems. Therefore, there is a need in the art to reduce the number of process operations and tools required to manufacture a PV device.

### SUMMARY

According to one or more embodiments, a photovoltaic (PV) device including a plurality of PV cells coupled in series, wherein the plurality of PV cells includes a first contact layer, a semiconductor layer disposed over the first contact layer, and a second contact layer disposed over the semiconductor layer, and a feature scribe that extends between a first PV cell and a second PV cell of the plurality of PV cells, the feature scribe exposing at least a portion of the first contact layer of the first PV cell and the second PV cell, and an insulating layer that covers at least a leading edge of the feature scribe and an exposed portion of the first contact layer of the first PV cell that is exposed in the feature scribe.

According to one or more embodiments, a photovoltaic (PV) device includes a plurality of PV cells coupled in series, wherein the plurality PV cells include a first contact layer, a semiconductor layer disposed over the first contact layer, and a second contact layer disposed over the semiconductor layer, and a feature scribe that extends between a first PV cell and a second PV cell of the plurality of PV cells, the feature scribe exposing at least a portion of the first contact layer of the first PV cell and the second PV cell, a first insulating layer positioned over at least the leading edge of the feature scribe and extends to a portion of the first contact layer of the second PV cell that is exposed by the feature scribe, and a second insulating layer that extends from a portion of the first contact layer located in the second PV cell exposed by the feature scribe to at least a trailing edge of the feature scribe.

According to one or more embodiments, a photovoltaic (PV) device includes a plurality PV cells coupled in series, wherein the plurality PV cells include a first contact layer, a semiconductor layer disposed over the first contact layer, and a second contact layer disposed over the semiconductor layer, and a feature scribe that extends between a first PV cell and a second PV cell of the plurality of PV cells and exposes a portion of the first contact layer of the first PV cell and the second PV cell, and an insulating layer including a first insulating layer portion that extends from at least a leading edge of the feature scribe to a portion of the first contact layer of the second PV cell located within the feature scribe, a second insulating layer portion that extends from a portion of the first contact layer of the second PV cell located within the feature scribe to at least a trailing edge of the feature scribe, and a feature formed between the first insulating layer portion and the second insulating layer portion that exposes a portion of the first contact layer within the feature scribe.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 illustrates an example of a photovoltaic device stack that includes multiple layers that may be used in a fully functioning PV cell and/or PV module, according to one or more embodiments.

FIG. 2A illustrates a schematic plan view of a photovoltaic device that includes a photovoltaic device array, according to one or more embodiments.

FIG. 2B illustrates a side cross-sectional view of a portion of the photovoltaic device array during fabrication, according to one or more embodiments.

FIG. 3 illustrates a method 300 of fabricating a portion of the photovoltaic device array of the photovoltaic device according to one or more embodiments.

FIGS. 4A-4M illustrate schematic cross-sectional views of a portion of the photovoltaic device array during various stages of the fabrication of the photovoltaic device, which relate to the operations found in the method illustrated in FIG. 3, according to one or more embodiments.

FIGS. 5A-5F illustrate schematic cross-sectional views of a portion of the photovoltaic device array during various stages of the fabrication of the photovoltaic device, which relate to the operations found in the method illustrated in FIG. 3, according to one or more embodiments.

FIGS. 6A-6F illustrate schematic cross-sectional views of a portion of the photovoltaic device array during various stages of the fabrication of the photovoltaic device, which relate to the operations found in the method illustrated in FIG. 3, according to one or more embodiments.

FIGS. 7A-7H illustrate schematic cross-sectional views of the portion of the photovoltaic device array during various stages of the fabrication of the photovoltaic device according to one or more embodiments.

FIG. 8 illustrates a method of fabricating the portion of the photovoltaic device array of the photovoltaic device found in the schematic cross-sectional views illustrated in FIGS. 7A-7H, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Perovskite photovoltaic solar devices, also generally referred to as PV devices, include a plurality of perovskite photovoltaic cells (PV cells) coupled in series. However, the manufacturing of thin film solar cell devices, such as perovskite photovoltaic solar devices require many deposition and patterning operations and tools. For example, manufacturing conventional PV devices can include the performance of about 13 to about 18 operations within a similar number of processing tools. The quantity of operations and tools is often due to the need for multiple laser scribing operations, which require the PV device to be moved in/out of deposition tools, which, for example, often include the use of a vacuum or ambient isolated processing environments to perform the deposition process.

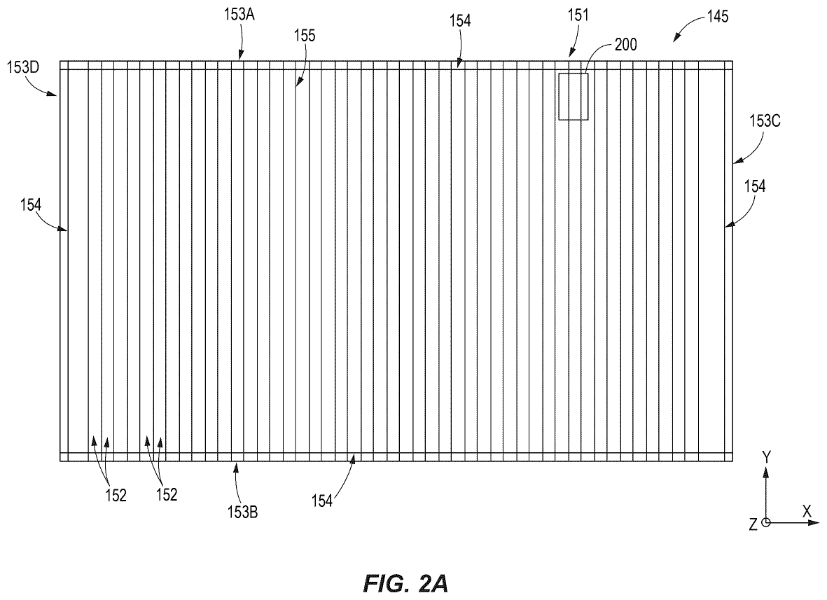

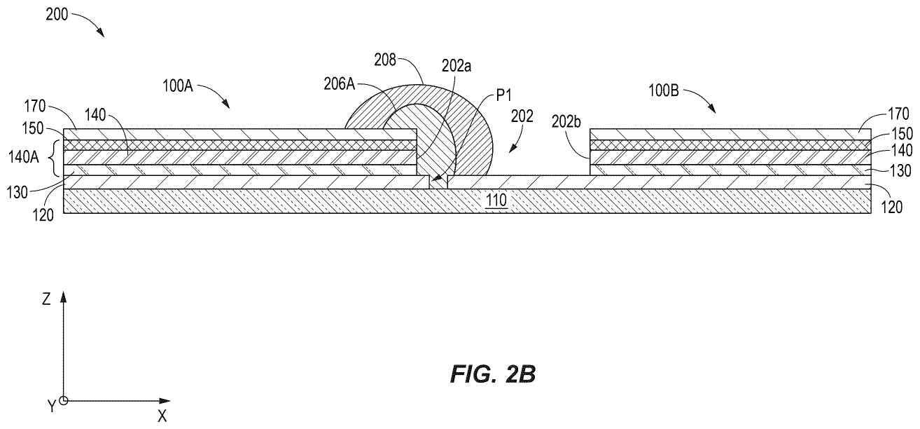

Embodiments herein relate to a PV device and corresponding method that includes the formation of feature scribes to interconnect PV cells within a PV module. In particular, embodiments herein relate to a PV device that includes a feature scribe that extends across portions of two adjacent PV cells within a PV module that includes a plurality of adjacent PV cells, as illustrated in FIG. 2A. As will be described in more detail below, the use of feature scribes in the process of forming a PV module reduces the quantity of separate scribing steps, the number of scribes, and the quantity of times the PV device needs to be transferred in and out of the deposition and other PV device processing chambers. The reduced quantity of separate scribing steps reduces the PV device formation process complexity and also the need to separately align and orient the PV modules within each of the scribing tools during each scribing step to accurately perform each subsequent scribing operation.

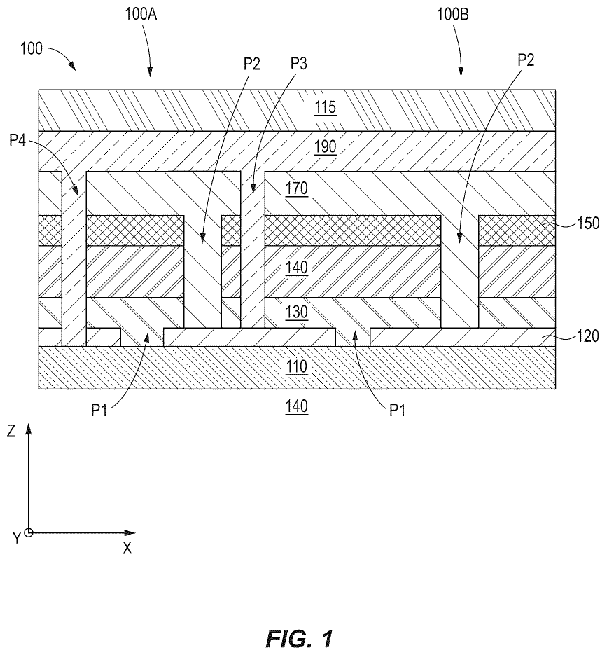

FIG. 1 illustrates an example of a photovoltaic device stack that forms part of a conventionally formed PV device. The photovoltaic device stack includes multiple layers that may be used in a fully functioning PV cell and/or PV module. In some embodiments of the present disclosure, a photovoltaic device 100, (e.g., a PV cell) may include, in order, a first substrate layer 110, a first contact layer 120, a first charge transport layer (CTL layer) 130, an absorber layer 140 (e.g., a perovskite layer), a second charge transport layer (CTL layer) 150, a second contact layer 170, an encapsulation layer 190, and a second substrate layer 115. To facilitate understanding, identical reference numerals have been used, where possible, to designate identical elements that are common to the figures. It is contemplated that elements and features of one embodiment may be beneficially incorporated in other embodiments without further recitation.

Referring again to FIG. 1, the conventional photovoltaic device 100 illustrated includes scribe lines that are used to separate portions of the absorber layer and/or other layers to form the individual PV cells within a formed PV module. In general, the term scribe line as used herein will include lines or channels formed in one or more materials or material layers to segment the material or material layers into smaller physically separated and in some cases electrically isolated regions within a PV cell, PV device, or PV module. Although the photovoltaic device 100 includes two PV cells 100A and 100B, this is for example purposes only, and it is understood that the photovoltaic device 100 can include any suitable quantity of PV cells.

The photovoltaic device 100, described herein may be a multilayer, stacked device that can include p-i-n or n-i-p type configuration. In one example, a PV cell within the photovoltaic device 100 may include, in order, a first charge transport layer (CTL layer) 130 that is a hole-transport-layer (HTL), an absorber layer 140 (e.g., a perovskite layer), a second charge transport layer (CTL layer) 150 that is an electron-transport-layer (ETL), and a second contact layer 170. In another example, a PV cell may include, in order, a first charge transport layer (CTL layer) 130 that is an electron-transport-layer (ETL), an absorber layer 140 (e.g., a perovskite layer), a second charge transport layer (CTL layer) 150 that is a hole-transport-layer (HTL), and a second contact layer 170.

In one or more embodiments, the photovoltaic device 100 includes first scribe lines P1. The first scribe lines P1 are formed in the first contact layer 120 that is formed on the first substrate layer 110. In one or more embodiments, the photovoltaic device 100 includes the second scribe lines P2 that are formed through the first CTL layer 130, absorber layer 140, and the second CTL layer 150 after the layers are formed over the first contact layer 120 and the first scribe lines P1. The P2 scribe lines are formed through the first CTL layer 130, absorber layer 140, and the second CTL layer 150 to separate portions of the formed layer stack and expose a portion of the first contact layer 120. In some embodiments, each of the formed second scribe lines P2 may extend into a portion of the first contact layer 120. The photovoltaic device 100 further includes third scribe lines P3, that are formed through the second contact layer 170, the second CTL layer 150, and at least a significant portion of the absorber layer 140, after the second contact layer 170 is formed over and within the formed second scribe lines P2. In some embodiments, the third scribe lines P3 may expose a portion of the first contact layer 120 and/or extend into a portion of the first contact layer 120. In one or more embodiments, the photovoltaic device 100 also includes a fourth scribe lines P4. The fourth scribe lines P4 are formed at the edge of the first substrate layer 110 of the photovoltaic device 100. The fourth scribe line P4, extends through the second contact layer 170, the second CTL layer 150, the absorber layer 140, the first CTL layer 130, and the first contact layer 120 and generally to the top surface of the first substrate layer 110. In some embodiments, the fourth scribe line P4 may extend into the first substrate layer 110.

The encapsulation layer 190 is disposed over the second contact layer 170 and fills the voids created by the third scribe lines P3 and the fourth scribe lines P4. In some embodiments, one or more barrier layers may be formed over the device stack. For example, the one or more barrier layers may be deposited over the second contact layer 170, and the exposed surfaces of the third scribe lines P3 and the fourth scribe lines P4, and partially fill the openings formed by the third scribe lines P3 and the fourth scribe lines P4. The encapsulation layer 190 may be formed over the one or more barrier layers. The second substrate layer 115 is disposed on and/or coupled to the encapsulation layer 190.

As noted above, a large quantity of operations and tools are required to form the conventional photovoltaic device 100 of FIG. 1. The large quantity of operations is due, at least in part, to the need for multiple laser scribing operations (P1-P4 scribes), which require the photovoltaic device 100 to be moved from in/out of deposition tools, which, for example, often include the use of a vacuum or ambient isolated processing environment to perform the deposition process.

As noted above, embodiments herein relate to a simplified PV cell interconnection process and configuration that includes the formation of a feature scribe that reduces the quantity of laser scribes and the quantity of times the photovoltaic device 100 would device need to be transferred between processing chambers and then separately aligned and oriented during each subsequent scribing operation.

FIG. 2A illustrates a schematic plan view of a photovoltaic device 145 that includes a photovoltaic device array 151 according to one or more embodiments. The photovoltaic device array 151 includes a plurality of series connected photovoltaic (PV) cells 152. The photovoltaic device array 151 includes a plurality of features, such as a plurality of first scribe lines P1 (not shown), a plurality of feature scribes 155 that extend between portions of adjacent PV cells (shown and described in more detail in FIGS. 2B-8 below) that are used to form the series connected PV cells 152. In some embodiments, the photovoltaic device 145 includes a plurality of fourth scribe lines 154 (also referred to as fourth scribe lines P4 in FIG. 1) that are used to separate and isolate the photovoltaic device array 151 from the edge regions of the photovoltaic device 145. For example, the photovoltaic device 145 includes top edge region 153A, bottom edge region 153B, left edge region 153C, and right edge region 153D. Advantageously, the process of forming the first scribe lines P1 and feature scribes 155 during the same processing step, as discussed further below, in lieu of separately forming the first scribe lines P1, the second scribe lines P2, and the third scribe lines P3 at different times during the photovoltaic device 145 formation sequence, dramatically simplifies the photovoltaic device 145 formation process. The photovoltaic device 145 formation process described herein reduces the quantity of laser scribing steps and related transferring and aligning operations required to form a PV device, which simplifies (e.g., speeds up and reduces the cost of) the process of forming the photovoltaic device 145.

FIG. 2B illustrates a side cross-sectional view of a portion 200 of the photovoltaic device array 151 during fabrication, according to one or more embodiments. As illustrated in FIG. 2, the portion 200 of the photovoltaic device array 151 includes the first substrate layer 110, the first contact layer 120, the first CTL layer 130, the absorber layer 140, and the second CTL layer 150. In one or more embodiments, as illustrated in FIG. 2B, the first CTL layer 130, the absorber layer 140, and the second CTL layer 150 together from a semiconductor layer 140A. For the ease of discussion, FIG. 2B does not include the encapsulation layer 190, the barrier layer, and any other layers positioned over the second contact layer 170.

As illustrated in FIG. 2B, the portion 200 of the photovoltaic device array 151 includes a PV cell 100A and a PV cell 100B that are separated by a feature scribe 202 that includes a first scribe line P1. The feature scribe 202 is formed through the second contact layer 170 and the semiconductor layer 140A. The feature scribe 202 exposes a portion of the first contact layer 120 within the PV cell 100A and the PV cell 100B. The feature scribe 202 extends between adjacent PV cells (i.e., the PV cell 100A to the PV cell 100B in FIG. 2B). The feature scribe 202 includes a leading edge 202a located in the PV cell 100A and a trailing edge 202b located in the PV cell 100B. The first scribe line P1 is positioned within the feature scribe 202 between the leading edge 202a and the trailing edge 202b. The first scribe line P1 can be formed within the feature scribe 202 before, during, or after the feature scribe 202 is formed. In one or more embodiments, as will be described in more detail below, instead of performing multiple scribes during formation of the photovoltaic device 100, (e.g., the second scribe line P2 and the third scribe line P3), the feature scribe 202 can be formed after deposition of the second contact layer 170, thus replacing the second scribe line P2 and the third scribe line P3. Advantageously, this reduces the use of multiple tools during the formation of the photovoltaic device 100 and simplifies (e.g., speed up and reduce the cost of) the process of forming the photovoltaic device 100.

Referring back to FIG. 2B, in one or more embodiments, the portion 200 of the photovoltaic device array 151 includes an insulating (electrically insulating) layer 206A. The insulating layer 206A covers at least the leading edge 202a of the feature scribe 202 and covers at least the exposed portion of the first contact layer 120 of the PV cell (i.e., PV cell 100A) that includes the leading edge 202a. In one example, the insulating layer 206A is formed so that it covers the exposed portion of the first contact layer 120 of the PV cell 100A and fills at least a portion of the first scribe line P1 adjacent to the exposed portion of the first contact layer 120 with the PV cell 100A. In one or more embodiments, the insulating layer 206A extends from a portion of the second contact layer 170 within the PV cell 100A and located outside of the feature scribe 202 to a portion of the first contact layer 120 within a portion of the PV cell 100B that is located within the feature scribe 202 and fills the entire first scribe line P1.

The insulating layer 206A isolates the second contact layer 170 from the first contact layer 120 within the PV cell 100A (a same PV cell). The insulating layer 206A prevents a short from being formed between the second contact layer 170 and the first contact layer 120 located in the PV cell 100A (i.e., the same PV cell). In one or more embodiments, as discussed further below, the insulating layer 206A includes, but is not limited to, an epoxy, urethane, acrylic, or other dispensable (e.g., ink-jet printable) electrically insulating material. In some configurations, the insulating layer 206A includes an insulating material that is curable, such as a ultraviolet (UV) light curable polymeric material. In one example, the insulating layer 206A includes a printable and photocurable composition that includes one or more urethane acrylate or urethane.

The photovoltaic device 100 further includes a conducting (electrically conducting) layer 208. The conducting layer 208 is positioned (formed) over the insulating layer 206A and extends from a portion of the second contact layer 170 located in the PV cell 100A to a portion of the first contact layer 120 of the PV cell 100B located within the feature scribe 202. The conducting layer 208 forms a series connection between the adjacent PV cells and thus allows current to flow between adjacent PV cells. Even though the feature scribe 202, insulating layer 206A, and conducting layer 208 are shown between only 2 adjacent PV cells, this is for ease of discussion purposes only. It is understood that the feature scribe 202, insulating layer 206A, and conducting layer 208 are formed between each set of adjacent PV cells in the photovoltaic device array 151.

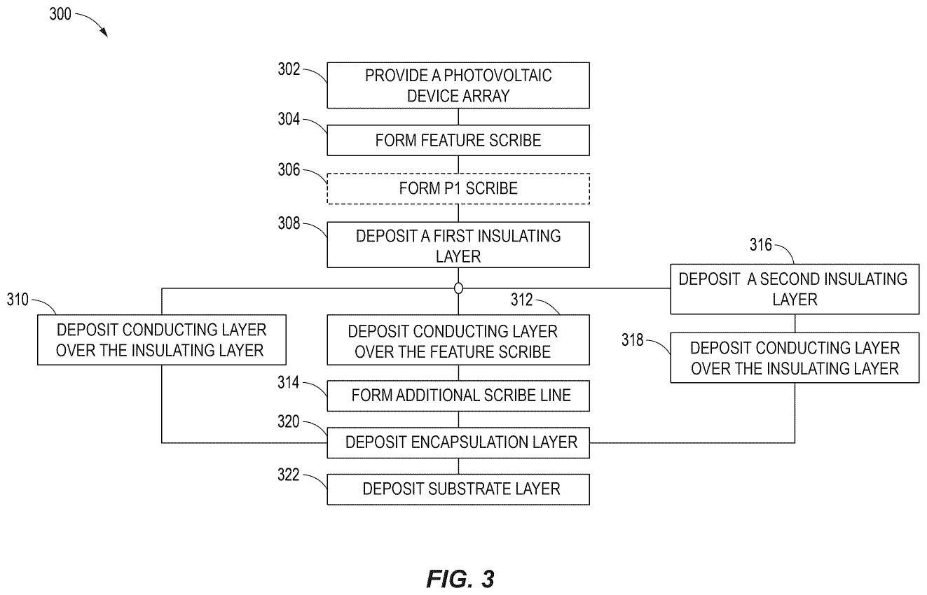

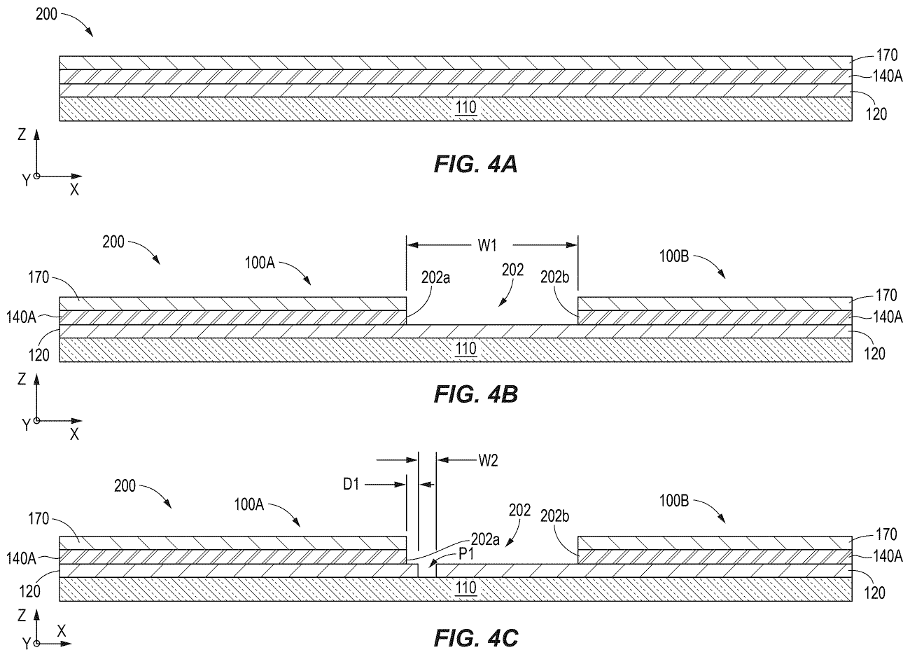

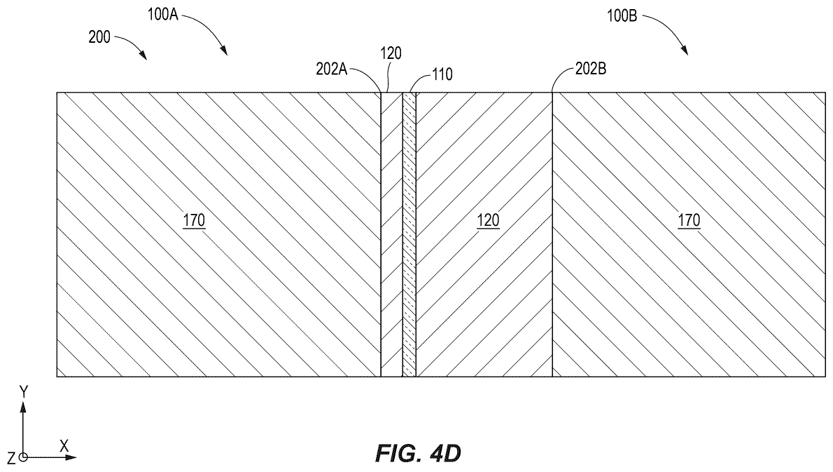

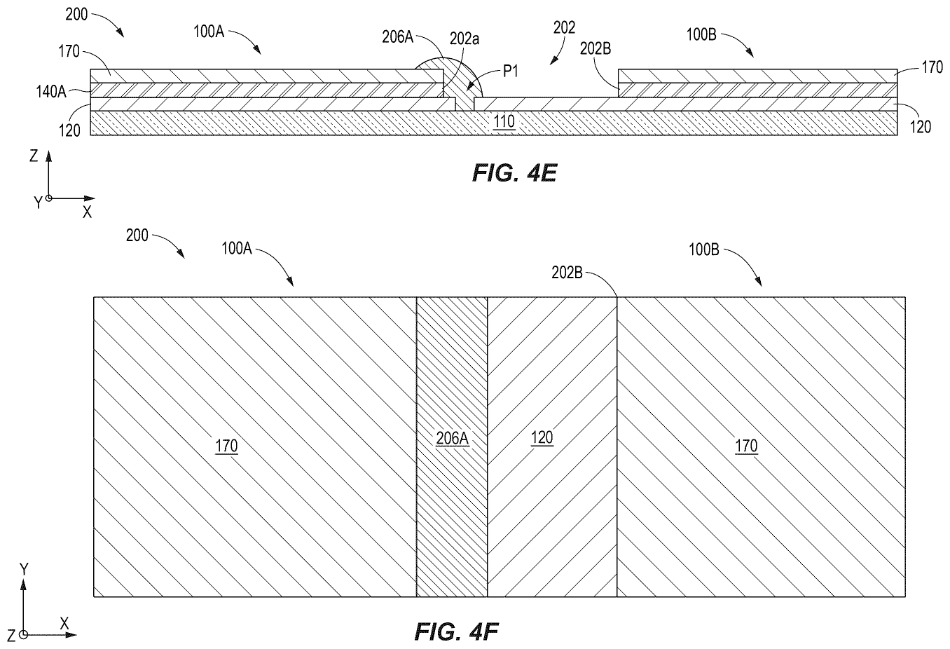

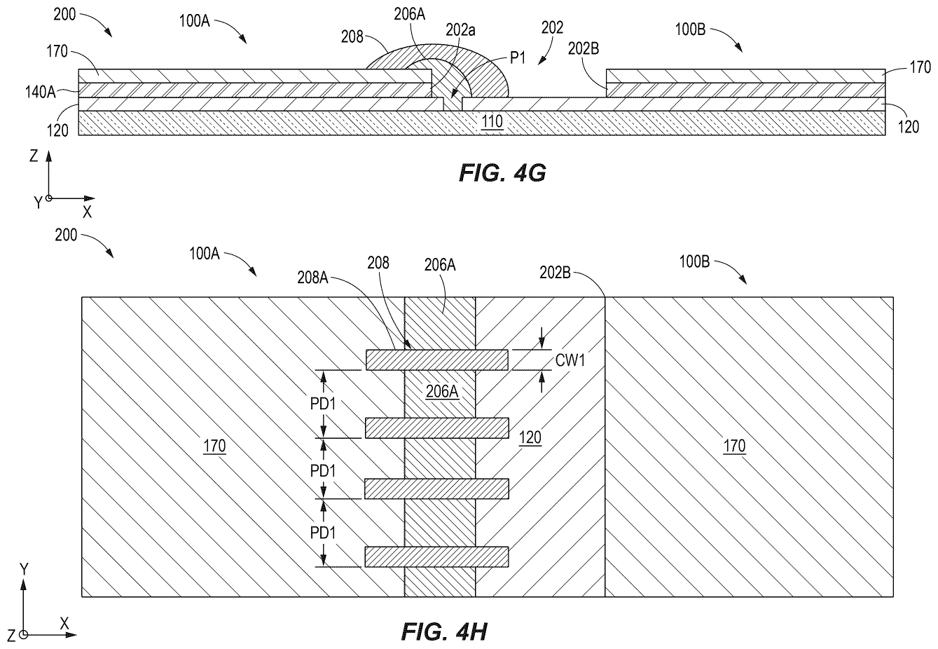

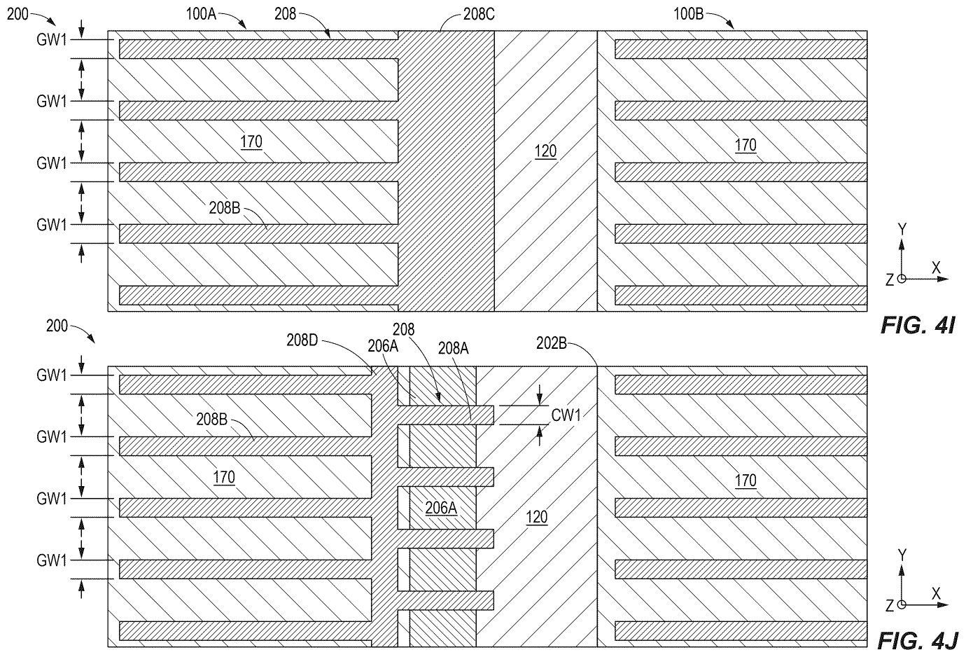

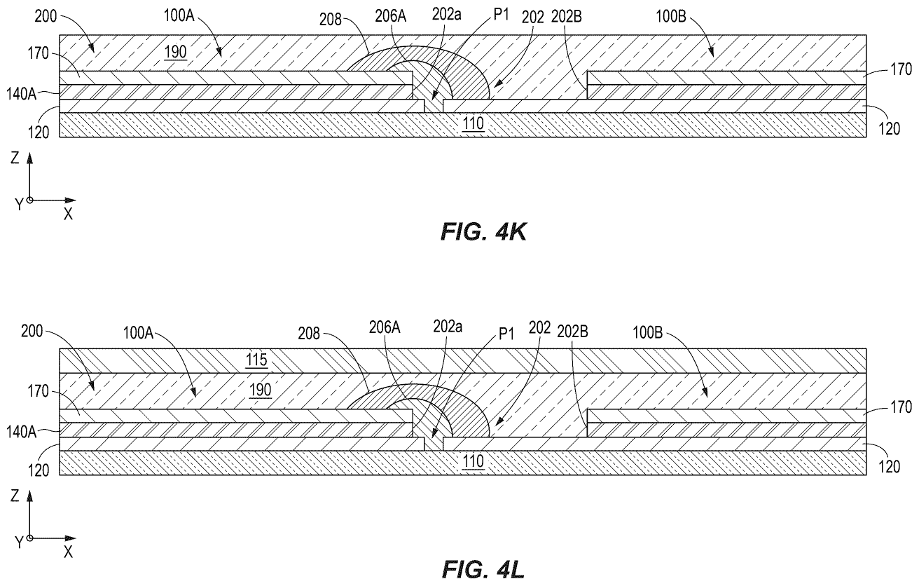

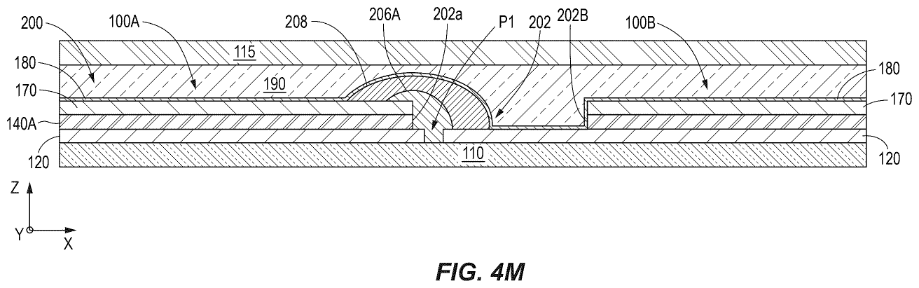

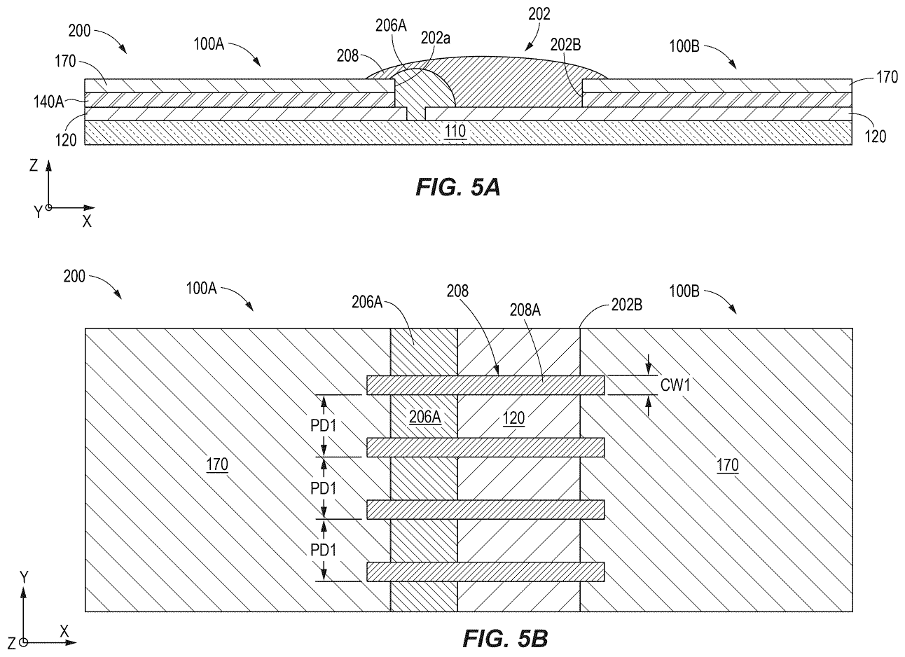

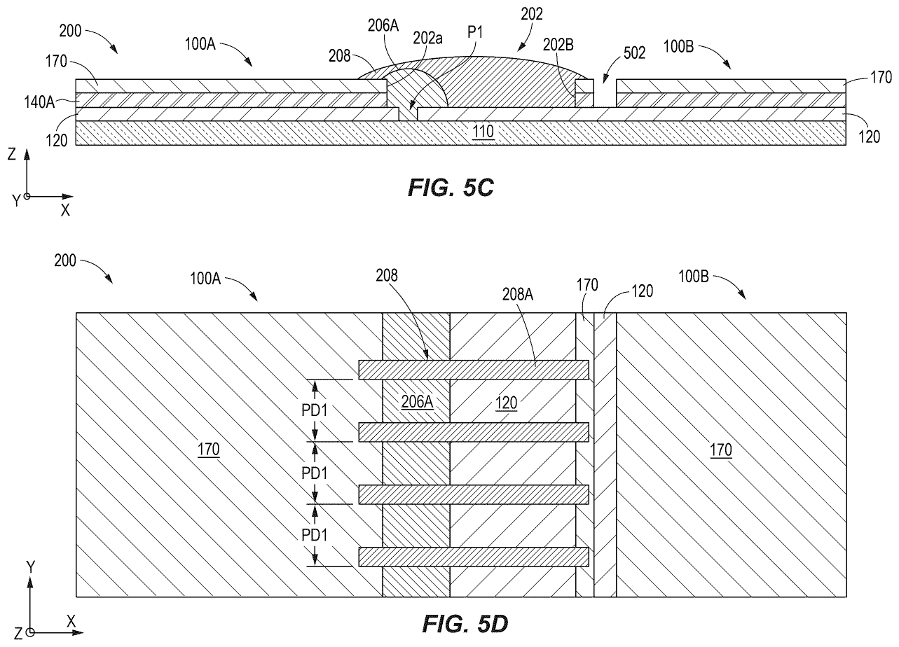

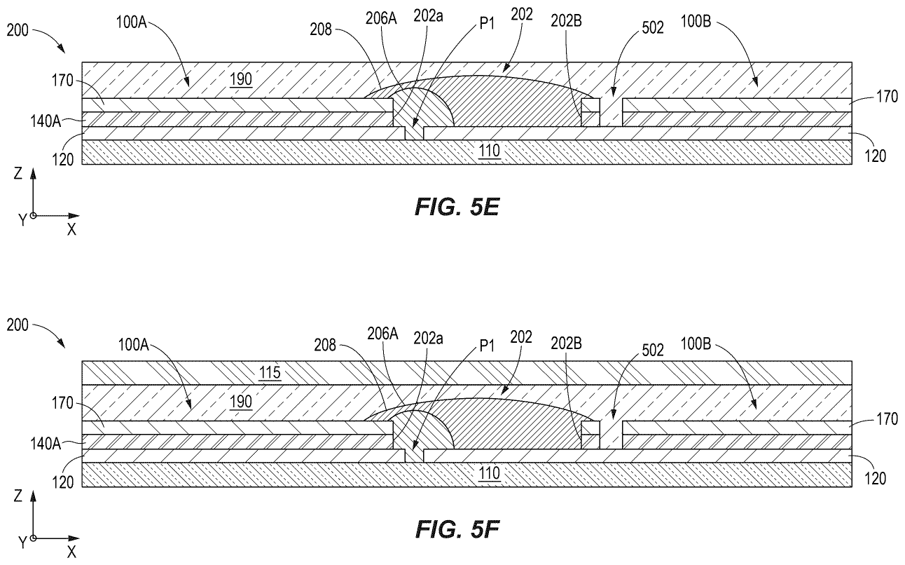

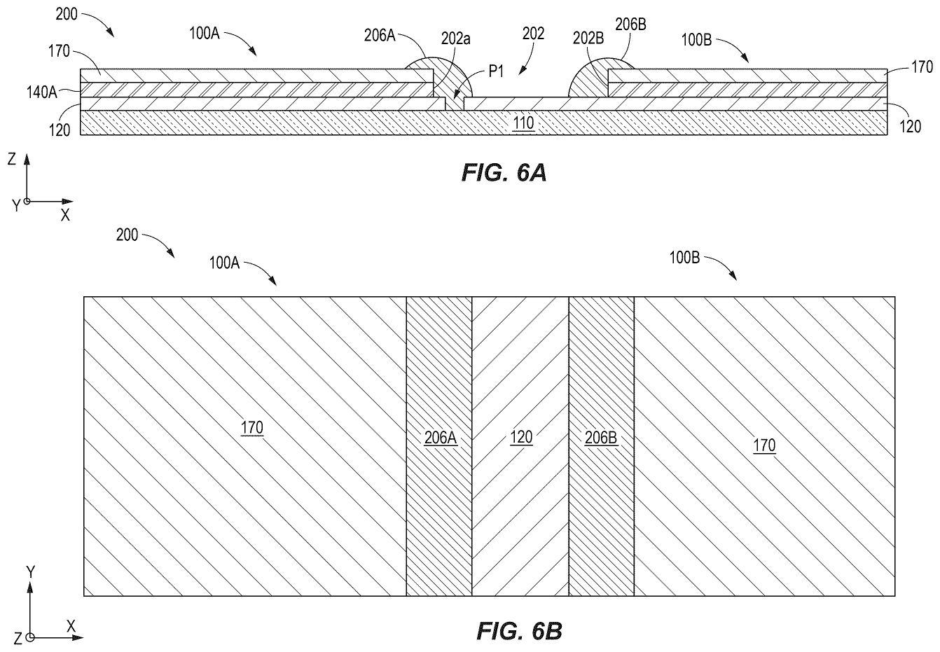

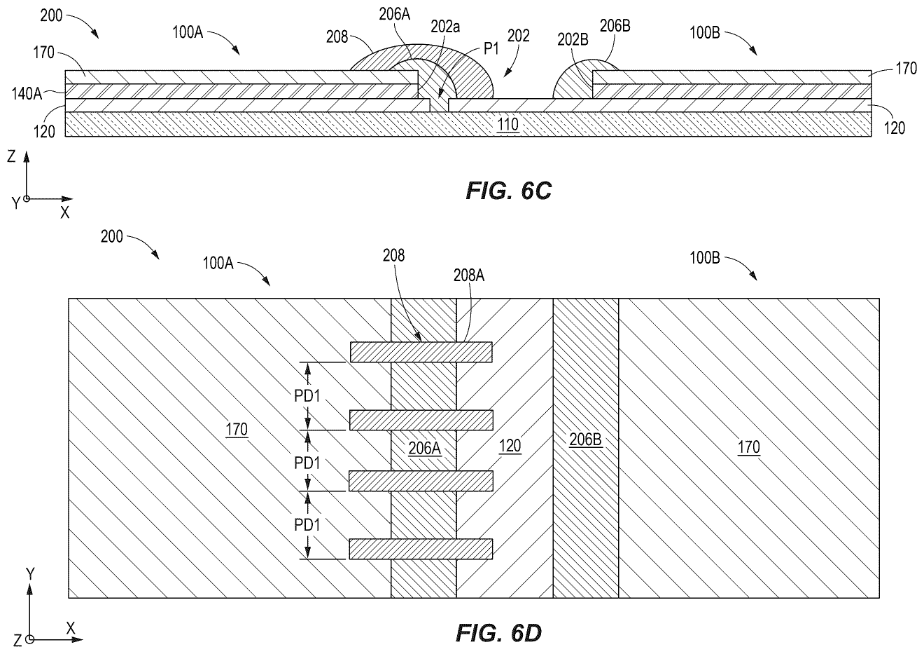

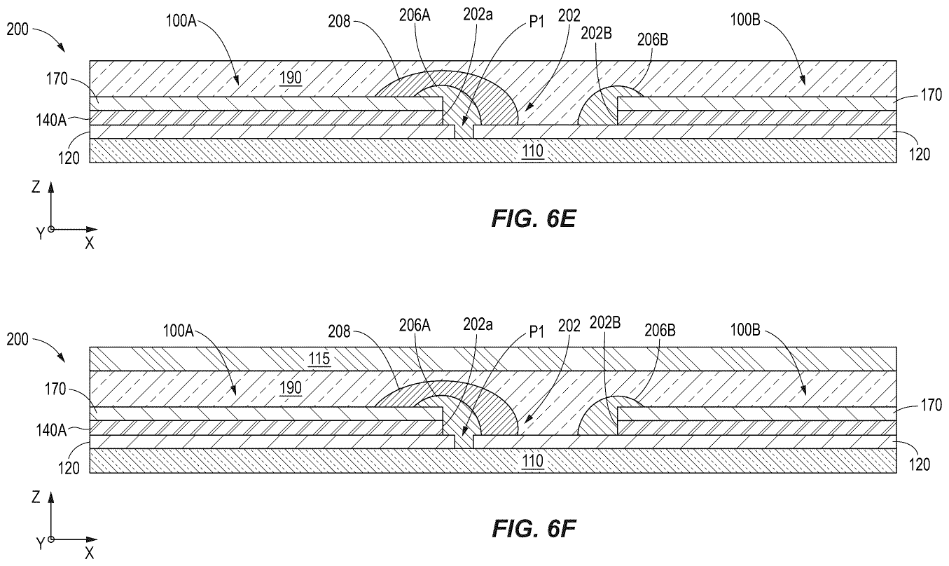

FIG. 3 illustrates a method 300 of fabricating a portion 200 of the photovoltaic device array 151 of the photovoltaic device according to one or more embodiments. FIGS. 4A-4J illustrate simplified schematic cross-sectional views of a portion of the photovoltaic device array during various stages of the fabrication of the photovoltaic device which relate to the operations found in the method illustrated in FIG. 3, according to one or more embodiments. FIGS. 5A-5F illustrate schematic cross-sectional views of a portion of the photovoltaic device array during various stages of the fabrication of the photovoltaic device which relate to the operations found in the method illustrated in FIG. 3, according to one or more embodiments. FIGS. 6A-6F illustrate schematic cross-sectional views of a portion of the photovoltaic device array during various stages of the fabrication of the photovoltaic device which relate to the operations found in the method illustrated in FIG. 3, according to one or more embodiments.

At operation 302, and as illustrated in FIG. 4A, a blanket deposited series of layers used to form PV cells within a photovoltaic device array 151 is provided. FIG. 4A illustrates a region in which a portion 200 of the photovoltaic device array 151 is to be formed. As noted above, the portion 200 includes the first contact layer 120, the semiconductor layer 140A, and the second contact layer 170 that are formed over the substrate layer 110. Due to the to be formed feature scribe 202, the semiconductor layer 140A and the second contact layer 170 can be deposited using blanket deposition processes prior to forming the interconnections between adjacent PV cells within a PV module, and thus simplifying the deposition processes and deposition process sequence required to form a PV device 145.

As noted above, the semiconductor layer 140A includes the first CTL layer 130, the absorber layer 140, and the second CTL layer 150. In some embodiments, the first CTL layer 130 may be configured to act as a hole transport layer (HTL) including a hole transport material, or to act as an electron transport layer (ETL) including an electron transport material. In some embodiments, the first CTL layer 130 may include a plurality of layers, where each layer of the plurality of layers may include a different material dependent upon the configuration (e.g., HTL versus ETL) of the first CTL layer 130. The first CTL layer 130 is an HTL that includes, but are not limited to, PTAA, Poly-TPD, nickel oxide, molybdenum oxide, OMATD, self-assembled monolayers (SAM), [2-(9H-carbazol-9-yl)ethyl]phosphonic acid (2PACz), (2-(3,6-Dimethoxy-9H-carbazol-9-yl)ethyl)phosphonic acid (MeO-2PACz), or (4-(3,6-Dimethyl-9H-carbazol-9-yl)butyl)phosphonic acid (Me-4PACz), (2-(3,6-Dibromo-9H-carbazol-9-yl)ethyl)phosphonic acid (Br-2PACz), or combinations thereof. In some embodiments, the first CTL layer 130, being configured to act as an HTL, may include a plurality of layers where each layer of the plurality of layers may include a different hole transport material. The different hole transport materials may include, but are not limited to, nickel oxide, PTAA, a SAM, or the like. For example, a multilayer HTL may include a plurality of layers where the plurality of layers comprise, nickel oxide and PTAA, nickel oxide and a SAM, a SAM and PTAA, or the like. As discussed above, in some embodiments, the first CTL layer 130, being configured to act as an ETL, may include a plurality of layers where each layer of the plurality of layers may include a different electron transport material. The different electron transport materials may include, but are not limited to combinations of tin dioxide (SnO₂), a SAM, titanium dioxide (TiO₂), zinc oxide (ZnO), or the like. For example, a multilayer ETL may a plurality of layers, where the plurality of layers comprise SnO₂ and a SAM, TiO₂ and ZnO, or the like.

The absorber layer 140 is formed over the first CTL layer 130. In some embodiments, the absorber layer 140 is disposed on the first CTL layer 130. In one or more embodiments, the absorber layer 140 is formed using a blanket deposition process over the first CTL layer 130. In some embodiments, the absorber layer 140 includes an absorber material that may include, a perovskite material. In one example, the absorber layer includes a perovskite material that has the stoichiometry of ABX₃, where A is a first cation, B is a second cation, and X comprises at least one halide (e.g., chloride, bromide, or iodide). In another example, the absorber layer 140 includes a perovskite that has a stoichiometry of ABX₃, where A comprises at least one of formamidinium (FA), methylammonium (MA), or cesium, and B comprises at least one of tin or lead, and X comprises at least one halide. In another example, the absorber layer 140 includes methylammonium lead tri-iodide (MAPbl3), cesium formamidinium methylammonium lead tri-iodide (CsFAMAPbl3), silicon (amorphous and/or crystalline), Group III-V materials (amorphous and/or crystalline), organic photovoltaic materials (OPV), dye-sensitized PV cells (DSSX), copper indium gallium selenide (CIGS), cadmium telluride (CdTe), or combinations thereof.

The absorber layer 140 may be formed by any suitable deposition process including, but not limited to, a vacuum deposition process, a solution based deposition process, or the like. In one or more embodiments, the solution based deposition process includes, but is not limited to, printing, slot-die coating, spray-coating, gravure printing, or any combination thereof. The deposited absorber layer 140 has an absorber layer thickness in the Z-direction between about 300 nm to about 900 nm. For example, the absorber thickness is between about 450 nm to about 950 nm, preferably between about 500 nm to about 650 nm. In some embodiments, the absorber layer 140 may have an absorber thickness between about 900 nm to about 2000 nm.

The second CTL layer 150 is deposited over the absorber layer 140 using a blanket deposition process. The second CTL layer 150 may be configured to act as a hole transport layer (HTL) including a hole transport material, or to act as an electron transport layer (ETL) including an electron transport material, which is an opposite carrier type of the carrier type found in the first CTL layer 130. In some embodiments, the second CTL layer 150 may include a plurality of layers, where each layer of the plurality of layers may include a different material dependent upon the configuration (e.g., HTL versus ETL) of the second CTL layer 150. In one example, the second CTL layer 150 is an ETL that includes, but is not limited to, a metal oxide such as at least one of TiO₂, SnO₂, Al₂O₃, ZnO, or carbon contacts such as carbon nanotubes, fullerenes (e.g., C₆₀ and or C₇₀), a fullerene derivative [6,6]-phenyl-C61-butyric acid methyl ester (PCBM), or fullerenes used alone or in conjunction with bathocuproine (BCP) or SnO₂, or other metal oxide, or combination thereof. As discussed above, in some embodiments, the second CTL layer 150, being configured to act as an ETL, may include a plurality of layers where each layer of the plurality of layers may include a different electron transport material. In one embodiment, the second CTL layer 150 includes a first sub-CTL layer and a second sub-CTL layer. For example, a multilayer ETL may a plurality of layers where the plurality of layers comprise C₆₀ or a self-assembled-monolayer (SAM), C₆₀ or BCP, or the like. The second CTL layer 150 has a second CTL layer thickness between about 0.1 nm to about 1 μm. The second CTL layer 150 may be formed by any suitable process including, but not limited to vacuum evaporation, atomic layer deposition, sputtering, chemical vapor deposition, or a combination thereof. In one or more embodiments, the first CTL layer 130 and the second CTL layer 150 may be doped differently from each other. For example, the first CTL layer 130 may be an n-type layer and the second CTL layer 150 may be a p-type layer (or vice versa).

In other embodiments, the second CTL layer 150 may be deposited over a buffer layer (not shown) formed over the absorber layer 140. In another example, a buffer layer may be formed over the second CTL layer 150. The buffer layer can comprise a material with a bandgap typically larger than the absorber layer 140, which may passivate the perovskite surface and/or slow the surface recombination rate, create a tunneling barrier, and/or otherwise change the interfacial properties between absorber layer 140 and the second CTL layer 150. The buffer layer can comprise, but is not limited to, oxides, oxysalts, sulfates, organics, organic salts, and fluorides. The buffer layer may be formed by any suitable process including, but not limited to a solution based deposition process, a chemical vapor deposition (CVD) process, plasma enhanced chemical vapor deposition (PECVD) process, an atomic layer deposition (ALD) process, a plasma enhanced atomic layer deposition (PEALD) process, a physical vapor deposition (PVD) process (e.g., evaporation process), or other suitable deposition technique. In one example, the deposited buffer layer has a total thickness between about 0.4 nm and about 40 nm.

The second contact layer 170 is formed over the second CTL layer 150, absorber layer 140, first CTL layer 130, first contact layer 120, and the first substrate layer 110. In one embodiment, the second contact layer 170 is disposed on the second CTL layer 150. The second contact layer 170 may be formed from any suitable contact layer material as described above. In one example, the second contact layer 170 includes a transparent conductive oxide (TCO) layer, such as an indium zinc oxide (IZO) or indium tin oxide (ITO) layer. The second contact layer 170 has a first thickness in the Z-direction of between about 5 nm to about 900 nm. The second contact layer 170 may be formed by any suitable process including, but not limited to a chemical vapor deposition (CVD) process, plasma enhanced chemical vapor deposition (PECVD) process, an atomic layer deposition (ALD) process, a plasma enhanced atomic layer deposition (PEALD) process, a physical vapor deposition (PVD) process, printing, spraying or other suitable deposition technique.

At operation 304, and as illustrated in FIG. 4B, the feature scribe 202 is formed in the portion 200 of the PV device 145. As noted above, the feature scribe 202 is formed after deposition of the second contact layer 170 replacing the second scribe line P2, and the third scribe line P3 used in a conventional PV module formation process. The feature scribe 202 is formed through the second contact layer 170, the semiconductor layer 140A, and exposes a portion of the first contact layer 120 within at least a portion of the second PV cell 100B. In one or more embodiments, the feature scribe 202 has a width W1 of about 30 nanometers (nm) to about 300 μm. The feature scribe 202 may be formed using any suitable scribing process including, but not limited to, mechanical scribing systems, laser ablation, or combination thereof. In one example, the scribing process includes the use of a laser that is configured to deliver coherent electromagnetic radiation at a wavelength of about 532 nanometers (nm).

At operation 306, and as illustrated in FIG. 4C, a first scribe line P1 is formed. As noted above the first scribe lines P1 are formed within feature scribes 202 throughout the photovoltaic device array 151. The first scribe lines P1 are formed through the first contact layer 120, and thus electrically separating the portions of the first contact layer 120 within adjacent PV cells. The first scribe lines P1 can include a lateral width W2 that is between about 10 μm and about 50 μm. The first scribe lines P1 may be formed using any suitable scribing process including, but not limited to, mechanical scribing systems, laser ablation, or a combination thereof. In one example, the P1 scribing process includes the use of a laser that is configured to deliver coherent electromagnetic radiation at a wavelength of about 1046 nanometers (nm). The first scribe lines P1 form electrically isolated regions of the first contact layer 120 that are each physically separated in the X-direction by the formed first scribe lines P1. Each of the electrically isolated regions include portions of the first contact layer 120 that are disposed within the PV cell 100A and the PV cell 100B. The first scribe lines P1 are formed a distance D1 in the X-direction measured from the leading edge 202a of the feature scribe 202. In one or more embodiments, the distance D1 can be equal to zero (0) or less than the lateral width W1 so long as a portion of the first contact layer 120 in the second PV cell 100B remains exposed within the feature scribe 202. In other words, the distance D1 is sized such that there is a space or a gap between the trailing edge of the first scribe lines P1 and the trailing edge 202b of the feature scribe 202. In one example, the distance D1 is about zero to about 50 μm less than the width W1 of the feature scribe 202.

FIG. 4D illustrates a top-view of the portion 200 of the photovoltaic device array 151. As shown in FIG. 4D, after operation 306, the first substrate layer 110 is exposed within the first scribe line P1 formed within the feature scribe 202. Additionally, the first contact layer 120 is exposed within the remainder of the feature scribe 202, and the leading edge 202a and the trailing edge 202b are exposed by the feature scribe 202.

At operation 308, as illustrated in FIG. 4E, an insulating layer 206A (a first insulating layer) is deposited. The insulating layer 206A covers at least the leading edge 202a of the feature scribe 202 and fills at least a portion of the first scribe line P1. In one or more embodiments, the insulating layer 206A further covers a portion of the second contact layer 170 of the PV cell 100A that is located outside of the feature scribe 202. In one or more embodiments, the insulating layer 206A extends from a portion of the second contact layer 170 within the PV cell 100A that is located outside of the feature scribe 202 to a portion of the first contact layer 120 within the PV cell 100B that is located within the feature scribe 202. The insulating layer 206A isolates the second contact layer 170 and the first contact layer 120 within the PV cell 100A (a same PV cell). The insulating layer 206A prevents a short between the second contact layer 170 and the first contact layer 120 located in the PV cell 100A (a same PV cell). In some embodiments, the insulating layer 206A includes a material selected from a group comprising an epoxy, urethane, acrylic, or other dispensable (e.g., ink-jet printable) electrically insulating material. In some configurations, the insulating layer 206A includes an insulating material that is curable, such as a ultraviolet (UV) light curable polymeric material. In one example, the includes a printable and photocurable composition that includes one or more urethane acrylate or urethane. The insulating layer 206A can also include a material that includes dielectric material containing nanoparticles, such as nanoparticles comprising silicon dioxide (SiO₂) or alumina (Al₂O₃), for example. The insulating layer 206A may be deposited by any suitable process including, but not limited to an additive manufacturing process, such as an ink-jet printing process, or other suitable deposition technique. The method used to deposit the insulating layer 206A can include an ink-jet printing type process that is configured to deliver micron scale droplet placement control of a photocurable material, within a print layer (X-Y resolution), as well as micron scale (1 μm to 200 μm) control over the thickness (Z resolution) of each print layer.

In one or more embodiments, the PV device 145 or portions of the PV device 145 can be formed in one or more interconnect configurations. FIGS. 4F-4H illustrate method steps (operations 310 and 320-322) of forming at least a portion of the PV device 145 in a first configuration. FIGS. 5A-5D illustrate method steps (operations 312-314 and 320-322) of forming at least a portion of the PV device 145 in a second configuration. FIGS. 6A-6D illustrate method steps of forming at least a portion of the PV device 145 in a third configuration (operations 316-318 and 320-322).

FIG. 4F illustrates a top-view of the portion 200 of the photovoltaic device array 151. As shown in FIG. 4F, after operation 308, a portion of the feature scribe 202, a portion of the second contact layer 170 within the PV cell 100A, and the leading edge 202a are covered by the insulating layer 206A. On the other hand, a portion of the feature scribe 202 (i.e., to right of the insulating layer 206A) still includes an exposed portion of the first contact layer 120 within the PV cell 100B and the trailing edge 202b.

At operation 310, and as illustrated in FIG. 4G, the conducting layer 208 is deposited over the insulating layer 206A. The conducting layer 208 is deposited over the insulating layer 206A and extends from (is in direct contact with) a portion of the second contact layer 170 within in the PV cell 100A located outside (to the left of the leading edge 202a) of the feature scribe 202 to a portion of the first contact layer 120 within the PV cell 100B that is located (exposed) within the feature scribe 202 (located between the first scribe line P1 and the trailing edge 202b). During operation 310, the conducting layer can be deposited in a first configuration shown in FIG. 4H, a second configuration shown in FIG. 4G, and a third configuration shown in FIG. 4H. The conducting layer 208 includes, but is not limited to, silver (Ag), a copper (Cu), carbon (C), or nickel (Ni), containing material paste (e.g., electrically calcined anthracite (ECA) containing paste), nanoparticle FTO, ITO, or ZnO: Al disposed in hexane (c60), and/or Ag nanowires, or any other suitable conductive material. The conducting layer 208 can be deposited using any suitable deposition process, including, but not limited to, an additive manufacturing process (e.g., inkjet process), or the like. As similarly discussed above, the method used to deposit the conducting layer 208 can include an ink-jet printing type process that is configured to deliver micron scale droplet placement control, within a print layer (X-Y resolution), as well as micron scale (1 μm to 200 μm) control over the thickness (Z resolution) of each print layer.

Even though the feature scribe 202, insulating layer 206A, and conducting layer 208 is shown in FIGS. 2B-4H as being disposed between only two adjacent PV cells, this is for example purposes only. It is understood that the feature scribe 202, insulating layer 206A, and conducting layer 208 are formed between each set of adjacent PV cells in the photovoltaic device array 151.

In one or more embodiments, the conducting layer 208 may be deposited in different configurations. FIGS. 4H-4J illustrate top-down views of the portion 200 in three example configurations. FIG. 4H illustrates a top-view of the portion 200 of the photovoltaic device array 151 including the conducting layer in a first configuration. As shown in FIG. 4H, the conducting layer 208 includes one or more conductive regions 208A (e.g., four are shown) that are spaced apart in a lateral direction (e.g., Y-direction). Each of the one or more conductive regions 208A extends over the insulating layer 206A and extends from (is in direct contact with) portions of the second contact layer 170 within in the PV cell 100A located outside (to the left of the leading edge 202a) of the feature scribe 202 to portions of the first contact layer 120 of the PV cell 100B located (exposed) within the feature scribe 202 (located between the first scribe line P1 and the trailing edge 202b). In one or more embodiments, the one or more conducting regions 208A have a width CW1 of about 20 μm to about 150 μm, for example, about 25 μm to about 75 μm. The one or more conductive regions 208A have a pitch PD1 in the Y-direction of about 50 μm to about 1 cm, for example about 150 μm to about 7 mm or about 300 μm to about 3 mm.

FIG. 4I illustrates a top-view of the portion 200 of the photovoltaic device array 151 including the conducting layer in the second configuration. As shown in FIG. 4I, the conducting layer 208 includes an interconnecting region 208C that is optionally connected to a plurality of gridlines 208B. The interconnecting region 208C extends across the entire length in the Y-direction of the feature scribe 202, as illustrated by the coverage shown in portion 200. As noted above, the interconnecting region 208C covers the insulating layer 206A, and extends from (is in direct contact with) a portion of the second contact layer 170 within the PV cell 100A located outside of the feature scribe 202 to a portion of the first contact layer 120 of the PV cell 100B located within the feature scribe 202. The gridlines 208B extend from the interconnecting region 208C in the X-direction and are deposited above the second contact layer 170. As understood by those with ordinary skill in the art, that a high electrical resistance can be formed across or through the second contact layer 170, restricting current flow between the PV cells. Advantageously, the gridlines 208B improve the collection of the generated current by each solar cell and allow the collected current to flow through the second contact layer 170. The gridlines 206B have a width GW1 of about 20 μm to about 100 μm, for example about 25 μm to about 50 μm, and a thickness (Z-direction) of about 1 μm to about 200 μm, for example about 15 μm to about 40 μm and about 30 μm to about 100 μm.

FIG. 4J illustrates a top-view of the portion 200 of the photovoltaic device array 151 including the conducting layer in the third configuration. As shown in FIG. 4J, the conducting layer 208 includes the one or more conductive regions 208A, an interconnecting gridline 208D, and the gridlines 208B. As shown in FIG. 4J, the interconnecting gridline 208D is formed over a portion the second contact layer 170 within the PV cell 100A (to the right of the insulation layer 206A) and is connected to both the gridlines 208B and the one or more conductive regions 208A. The gridlines 208B can have a width GW1 of about 20 μm to about 100 μm and a thickness (Z-direction) of about 1 μm to about 200 μm, and the interconnecting gridline 208D can have a width of about 1 μm to about 100 μm and a thickness (Z-direction) of about 1 μm to about 200 μm.

In one or more embodiments, after operation 310, at operation 320 the encapsulation layer 190 is deposited and/or formed over the portion 200. As illustrated in FIG. 4K, the encapsulation layer 190 is disposed over exposed portions second contact layer 170 of both PV cells 100A and 100B, the conducting layer 208, and fills the voids in the feature scribe 202 (i.e., covers the exposed portions of the first contact layer 120 within the feature scribe 202). The encapsulation layer 190 includes an encapsulation material. The encapsulation material may include, but is not limited to, ethylene vinyl acetate (EVA), polyolefin, polyurethane, polyvinyl butyral, ionomers or combination thereof. The encapsulation layer 190 has an encapsulation thickness between about 0.1 mm to about 5 mm. The encapsulation layer 190 may be formed by any suitable process including, but not limited to, a lamination process, casting, an autoclave process, or other common deposition and/or attachment techniques.

In some embodiments, one or more barrier layers 180 (FIG. 4M) may be formed over the device stack, and thus before operations 320 and 322 are performed. For example, the one or more barrier layers may be deposited over the second contact layer 170, and the exposed surfaces of the fourth scribe lines P4, and partially fill the openings formed by the feature scribe 202. The barrier layer 180 can be deposited conformally over the exposed surfaces of the photovoltaic device array 151 before operation 320 is performed, as illustrated in the portion 200 shown in FIG. 4M. Then, during operation 320, the encapsulation layer 190 can be formed over the one or more barrier layers 180. The one or more barrier layers include a barrier material. Each barrier layer of the one or more barrier layers may include a different barrier material. The barrier layer 180 can have a thickness of about 0.5 μm to about 20μm, such as about 10 μm to about 20 μm. In one example, the barrier layer 180 can also include a multilayer stack that can include an inorganic material-containing layer and an organic material-containing layer. The barrier materials of the one or more barrier layers may include an inorganic material-containing layer, such as a metal oxide containing layer. In one example, the one or more barrier layers include, but are not limited to, a material that comprises aluminum oxide, silicon oxide, tin oxide, titanium oxide, zirconium oxide, or combination thereof. The barrier layer 180 materials of the one or more barrier layers may include a styrenic polymer, a polysiloxane, an amine-containing polymer, a polyacrylate, an aryl ammonium halide, an alkyl ammonium halide, a fluorinated hydrocarbon polymer, or a combination thereof. In another example, the one or more barrier layers include, but are not limited to, a styrenic polymer such as polystyrene (PS), acrylonitrile butadiene styrene (ABS), acrylonitrile-styrene-acrylate (ASA) or styrene-butadiene rubber (SBR). In another example, the one or more barrier layers include, but are not limited to, a polysiloxane such as poly(dimethylsiloxane), poly(diethylsiloxane) or poly(methylphenylsiloxane). In another example, the one or more barrier layers include, but are not limited to, a amine-containing polymer such as polyethylenimine (PEIE), poly(vinylamine) hydrochloride (PVH), or poly(ethylene glycol) bis(amine) (PEG-Amine). In another example, the one or more barrier layers include, but are not limited to, a polyacrylate such as polymethylmethacrylate (PMMA) or polyethylacrylate. In another example, the one or more barrier layers include, but are not limited to, an aryl ammonium halide such as phenethylammonium iodide (PEAI), 1-(ammonium acetyl) pyrene (PEY) or dodecyl ammonium-chloride (DACI). In another example, the one or more barrier layers include, but are not limited to, an alkyl ammonium halide such as n-propylammonium iodide (PAI), ethane-1,2-diammonium (EDA), 2-chloroethylamine (CEA) or 2-bromo-ethylamine (BEA). In another example, the one or more barrier layers include, but are not limited to, a fluorinated hydrocarbon polymer such as Nafion™, polytetrafluoroethylene, polyvinylidene-fluoride, or trifluoroethylene. The one or more barrier layers have a barrier thickness between about 1 nm to about 5 μm. The one or more barrier layers may be conformally deposited by any suitable process, for example, a chemical vapor deposition (CVD) process, plasma enhanced chemical vapor deposition (PECVD) process, an atomic layer deposition (ALD) process, a plasma enhanced atomic layer deposition (PEALD) process, a physical vapor deposition (PVD) process (e.g., thermal evaporation), or solution processing methods such ink-jet printing, slot-die coating, spray-coating, gravure printing, blanket coating. In some embodiments, the solution processing methods include an annealing process.

At operation 322, as shown in FIG. 4L, the second substrate layer 115 is disposed on and/or coupled to the encapsulation layer 190. The second substrate layer 115 has a second substrate thickness between about 0.05 mm to about 5 mm. In some embodiments, as discussed above, second substrate layer 115 can include one or more materials selected from a group that includes a metal foil, silicon, glass, and/or a polymer substrate. In some embodiments, the second substrate layer 115 is glass with a thickness between about 1 mm and 3 mm.

In one additional or alternate configuration of the interconnection(s) formed between adjacent PV cells, as illustrated in FIGS. 5A-5D, after operation 308, the method 300 may continue to operations 312-314 instead of operation 310.

At operation 312, and as illustrated in FIG. 5A, the conducting layer 208 is deposited over the insulating layer 206A and exposed portions of feature scribe 202. In this configuration, the conducting layer 208 extends from (is in direct contact with) a portion of the second contact layer 170 located within in the PV cell 100A and outside of the feature scribe 202 (to the left of the leading edge 202a) and a portion of the second contact layer 170 located within in the PV cell 100B and outside of the feature scribe 202 (to the right of the trailing edge 202b). Additionally, the conducting layer 208 is deposited over the exposed portions of the first contact layer 120 located within the feature scribe 202.

FIG. 5B illustrates a top-view of the portion 200 of the photovoltaic device array 151 including the conducting layer 208. As shown in FIG. 5B, the conducting layer 208 includes the one or more conductive regions 208A. While FIG. 5B illustrates a conductive layer 208 configuration that includes multiple discrete conducting regions 208A, which is similar to the configuration illustrated in FIG. 4H, the conducting layer 208 could also be similarly configured as the conductive layer 208 shown in FIGS. 4I-4J.

At operation 314, and as illustrated in FIG. 5C, an additional scribe line 502 is formed. In one or more embodiments, the additional scribe line 502 is formed in a portion of the PV cell 100B located outside of the feature scribe 202 and that does not have the conducting layer 208 formed thereon. The additional scribe line 502 is formed through at least the second contact layer 170. For example, the additional scribe is formed through the second contact layer 170 and the semiconductor layer 140A, and exposes the first contact layer 120. In other embodiments, the additional scribe line 502 is located close to the exposed trailing edge in the PV cell 100B so that the additional scribe line 502 is located where portions of the second contact layer 170 are overcoated with the conducting layer 208 so the additional scribe line 502 is formed through at least the second contact layer 170 and the conducting layer 208. In one or more embodiments, the additional scribe 502 prevents a short between the second contact layers 170 within the adjacent PV cells 100A and 100B.

FIG. 5D illustrates a top-view of the portion 200 of the photovoltaic device array 151, including the additional scribe line 502. As shown in FIG. 5D, the first contact layer 120 is exposed due to the additional scribe line 502.

In one or more embodiments, after operation 314, the method 300 proceeds to operation 320 and the encapsulation layer 190 is deposited and/or formed over the portion 200. As illustrated in FIG. 5E, the encapsulation layer 190 is disposed over exposed portions second contact layer 170 of both PV cells 100A and 100B, the conducting layer 208, and fills the voids in the additional scribe line 502.

At operation 322, as shown in FIG. 5F, the second substrate layer 115 is disposed on and/or coupled to the encapsulation layer 190.

In one or more embodiments, the optional barrier layer 180 can be deposited over the exposed surfaces of the PV cells prior to performing operation 320 in the same manner as described above in relation to FIG. 4M. In this case, referring to FIG. 5F, the barrier layer 180 would be formed over the exposed portions of the second contact layer 170, over the conducting layer 208, any exposed portions of the insulating layer 206, at least coat the surfaces of the feature scribe 202, and at least coat the surfaces of the additional scribe 502.

In one additional or alternate configuration of the interconnection(s) formed between adjacent PV cells, as illustrated in FIGS. 6A-6F, after operation 308, the method 300 may continue to operations 316-318 instead of operation 310 or operations 314-316.

At operation 316, and as illustrated in FIG. 6A, an insulating layer 206B (a second insulating layer) is deposited. The insulating layer 206B can include the same material as the insulating layer 206A and be deposited simultaneously or sequentially with the insulating layer 206A using an additive manufacturing process. The ability to deposit the insulating layers 206A and 206B simultaneously or sequentially will reduce the need for additional alignment steps to position the insulating layers within the feature scribe 202 correctly. The insulating layer 206B is located over a portion of the PV cell 100B and extends from a portion of the first contact layer 120 exposed by the feature scribe 202 to at least the trailing edge 202b. In one or more embodiments, the insulating layer 206B further extends to a portion of the second contact layer 170 located in the PV cell 100B outside of the feature scribe 202, as illustrated in FIG. 6A. The second insulating layer covers the trailing edge 202b of the feature scribe 202 and isolates the exposed first contact layer 120 from the second contact layer 170 within the PV cell 100B to prevent a short and provide additional protection during deposition of the conducting layer 208 in a subsequent operation.

FIG. 6B illustrates a top-view of the portion 200 of the photovoltaic device array 151. As shown in FIG. 6B, after operation 316, the portions of the first contact layer 120 located between the insulating layer 206A and the insulating layer 206B are exposed in the feature scribe 202 while the leading edge 202a is covered by the insulating layer 206A and the trailing edge 202b is covered by the insulating layer 206B.

At operation 318, the conducting layer 208 is deposited. As illustrated in FIGS. 6C-6D, the conducting layer 208 is deposited in the same manner described in operation 310. Although FIG. 6D illustrates the conductive layer 208 in the first configuration (FIG. 4H), it is understood that the conductive layer 208 illustrated in FIGS. 6C-6D can also have any of the configurations described in FIGS. 4H-4J.

In one or more embodiments, after operation 318, the method 300 proceeds to operation 320 and the encapsulation layer 190 is deposited and/or formed over the portion 200. As illustrated in FIG. 6E, the encapsulation layer 190 is disposed over exposed portions second contact layer 170 of both PV cells 100A and 100B, the conducting layer 208, the insulating layer 206B, and fills the voids in the feature scribe 202. At operation 322, as shown in FIG. 6F, the second substrate layer 115 is disposed on and/or coupled to the encapsulation layer 190.

In one or more embodiments, the optional barrier layer 180 can be deposited over the exposed surfaces of the PV cells prior to performing operation 320 in the same manner illustrated in FIG. 4M. In the configuration of FIG. 6F, the barrier layer 180 would be formed over the exposed portions of the second contact layer 170,, over any exposed surfaces of the insulating layer 206, and over the conducting layer 208.

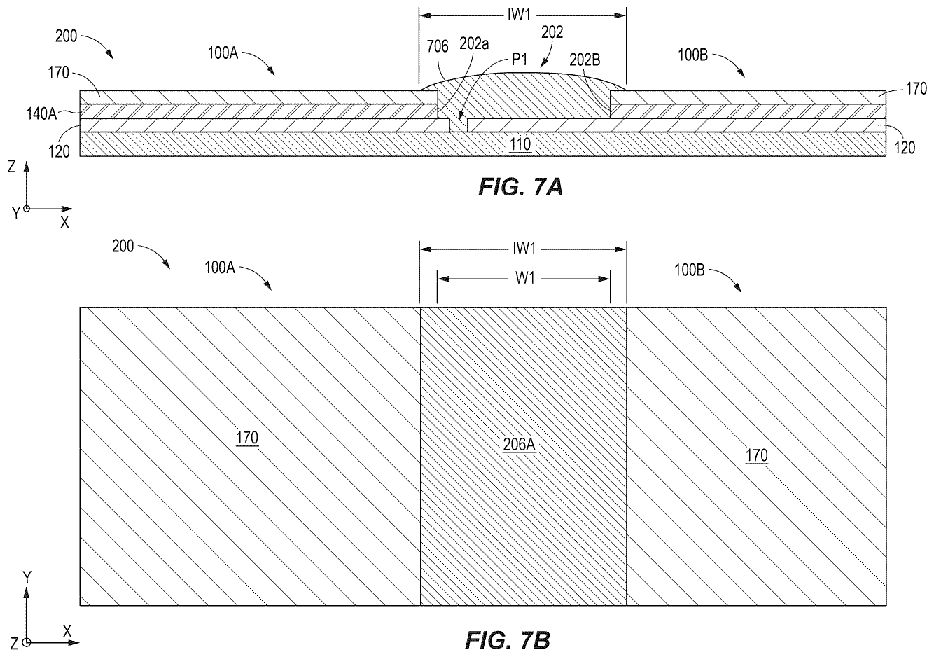

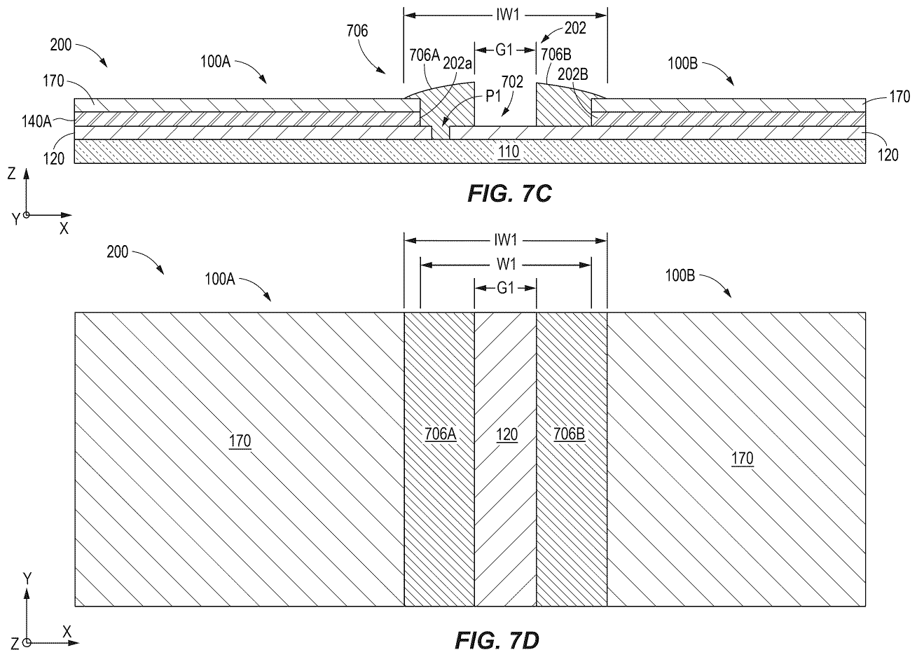

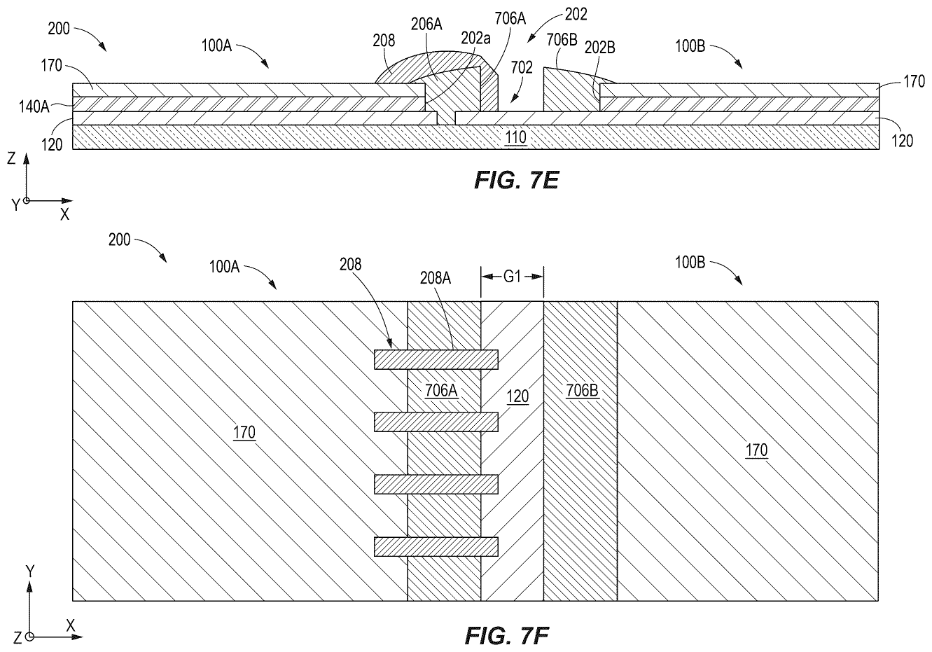

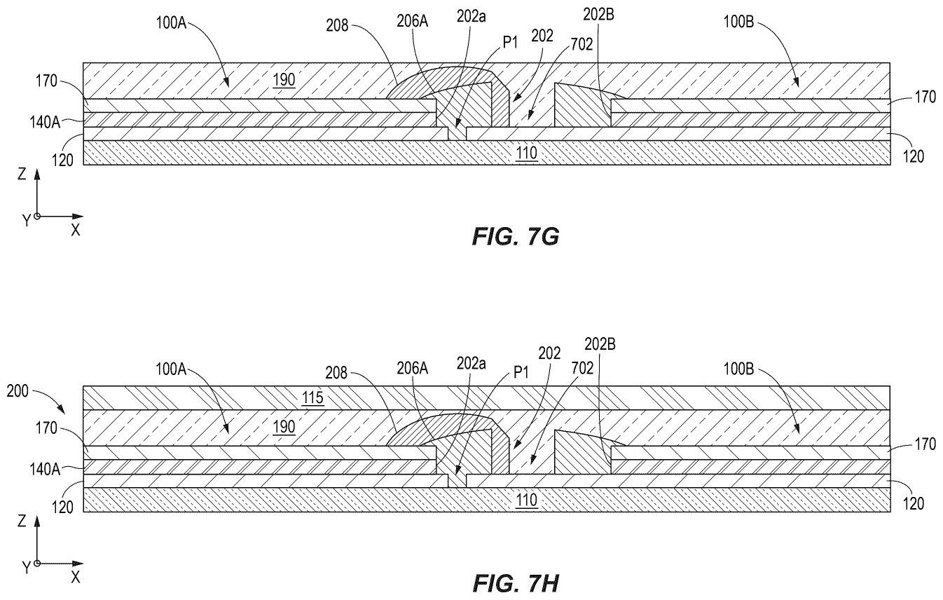

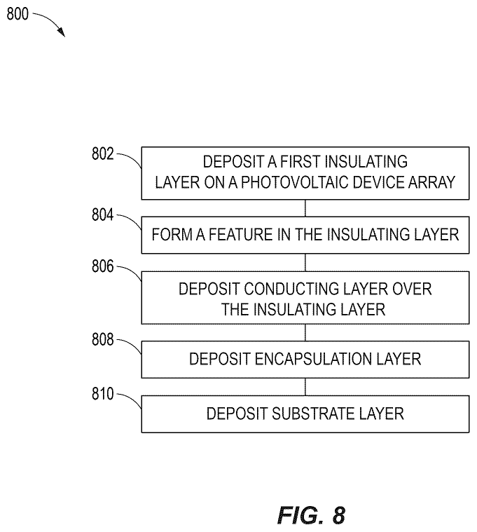

FIGS. 7A-7H illustrate schematic cross-sectional views of the portion 200 of the photovoltaic device array 151 during various stages of the fabrication of the photovoltaic device according to one or more embodiments. FIG. 8 illustrates a method 800 of fabricating the portion 200 of the photovoltaic device array 151 of the photovoltaic device found in the schematic cross-sectional views illustrated in FIGS. 7A-7H, according to one or more embodiments.

At operation 802, as illustrated in FIG. 7A, an insulating layer 706 is deposited over the photovoltaic device array 151 using an additive manufacturing process, such as one or more of the processes described above. In the same manner described above, FIG. 7A illustrates the portion 200 of the photovoltaic device array 151. In the configuration illustrated in FIG. 7A, the insulating layer 706 extends across the entire feature scribe 202. In one or more embodiments, the insulating layer 706 extends from the leading edge 202a to the trailing edge 202b. In one or more embodiments, the insulating layer further extends from a portion of the second contact layer 170 within in the PV cell 100A located outside of the feature scribe 202 (to the left of the leading edge 202a) to a portion of the second contact layer 170 within in the PV cell 100B located outside of the feature scribe 202 (to the right of the trailing edge 202b), as shown in FIG. 7A. The insulating layer 706 has a width IW1 of about 30 μm to about 360 μm. The width IW1 is greater than the width W1 of the feature scribe 202. The insulating layer 706 can include one or more of the materials disposed within the insulating layer 206A, 206B described above.

FIG. 7B illustrates a top-view of the portion 200 of the photovoltaic device array 151. As shown in FIG. 7B, after operation 802, the insulating layer 706 fills, and therefore, covers the feature scribe 202.

At operation 804, and as illustrated in FIG. 7C, a feature 702 is formed through the insulating layer 706. The feature 702 extends through the insulating layer 706 and exposes the first contact layer 120. The feature 702 forms an insulating layer portion 706A that covers the leading edge 202a and extends from a portion of the second contact layer 170 located in the PV cell 100A and outside of the feature scribe 202 to a portion of the first contact layer 120 of the PV cell 100B located within the feature scribe 202. The feature 702 forms an insulating layer portion 706B that covers the trailing edge 202b and extends from a portion of the first contact layer 120 located within the PV cell 100B, which was exposed by the feature scribe 202, to a portion of the second contact layer 170 of the PV cell 100B located outside of the feature scribe 202. The feature 702 has a width G1 that is less than the width IW1. The width G1 is from about 5 μm to about 270 μm. The feature 702 may be formed using any suitable scribing process including, but not limited to, mechanical scribing systems, laser ablation, or combination thereof. In one example, the scribing process includes the use of a laser that is configured to deliver coherent electromagnetic radiation at a wavelength of about 532 nanometers (nm).

FIG. 7D illustrates a top-view of the portion 200 of the photovoltaic device array 151. As shown in FIG. 7D, after operation 322, the first contact layer 120 is visible across the width G1.

At operation 806, and as illustrated in FIG. 7E, the conducting layer 208 is deposited over the insulating layer 706. The conducting layer 208 extends over the insulating layer portion 706A and extends from (is in direct contact with) a portion of the second contact layer 170 within in the PV cell 100A located outside (to the left of the leading edge 202a) of the feature scribe 202 to a portion of the first contact layer 120 within the PV cell 100B that is located (exposed) within the feature 702.

FIG. 7F illustrates a top-view of the portion 200 of the photovoltaic device array 151. As shown in FIG. 7D, after operation 806, the conducting layer 208 includes the conducting regions 208A that extend between the portion of the second contact layer 170 within in the PV cell 100A located outside of the feature scribe 202 and a portion of the first contact layer 120 within the PV cell 100B that is located (exposed) within the feature 702. Although FIG. 7F illustrates the conductive layer 208 in the first configuration (FIG. 4H), it is understood that the conductive layer 208 illustrated in FIGS. 6E-6H can also have any of the configurations described in FIGS. 4H-4J.

In one or more embodiments, after operation 806, the method 800 proceeds to operation 808 and the encapsulation layer 190 is deposited and/or formed over the portion 200. As illustrated in FIG. 7G, the encapsulation layer 190 is disposed over exposed portions second contact layer 170 of both PV cells 100A and 100B, the conducting layer 208, the insulating layer portion 706B, and fills the voids in the feature 702 (i.e., covers the portions of the first contact layer 120 exposed by the feature 702).

At operation 810, as shown in FIG. 7H, the second substrate layer 115 is disposed on and/or coupled to the encapsulation layer 190.

In one or more embodiments, the optional barrier layer 180 can be deposited over the exposed surfaces of the PV cells prior to performing operation 320 in the same manner illustrated in FIG. 4M. In the configuration of FIG. 7H, the barrier layer 180 would be formed over the exposed portions of the second contact layer 170, over the conducting layer 208, over any exposed surfaces of the insulating layer 206, at least coat the surfaces of the feature 702, and over the insulating layer portion 706B.

As noted above, embodiments herein relate to a feature scribe 202 that extends between two adjacent PV cells of a photovoltaic device 100. Advantageously, the feature scribe 202 reduces the number of scribes and scribing processes required to form the photovoltaic device 100. The feature scribe 202 reduces the use of multiple tools during the formation of the photovoltaic device 100 and simplifies (e.g., speed up and reduce the cost of) the process of forming the photovoltaic device 100.

Embodiments include a photovoltaic (PV) device includes: a plurality of PV cells coupled in series, wherein the plurality of PV cells includes a first contact layer a semiconductor layer disposed over the first contact layer, and a second contact layer disposed over the semiconductor layer, and a feature scribe that extends between a first PV cell and a second PV cell of the plurality of PV cells, the feature scribe exposing at least a portion of the first contact layer of the first PV cell and the second PV cell, and an insulating layer that covers at least a leading edge of the feature scribe and an exposed portion of the first contact layer of the first PV cell that is exposed in the feature scribe.

In one or more embodiments of the PV device the feature scribe is formed through a portion of the second contact layer and at least a portion of the semiconductor layer of the first PV cell and the second PV cell.

In one or more of the previous embodiments, the PV device can further include the feature scribe has a width of about 30 μm to about 300 μm.

In one or more of the previous embodiments, the PV device can further include a conducting layer disposed over the insulating layer that extends from a portion of the second contact layer located in the first PV cell to a portion of the first contact layer of the second PV cell exposed by the feature scribe. In some embodiments the conducting layer comprises a plurality of conducting regions that extend from portions of the second contact layer located in the first PV cell to portions of the first contact layer of the second PV cell exposed by the feature scribe. In some embodiments the conducting layer further comprises an interconnecting region connected to the plurality of conducting regions to gridlines that are connected to the interconnecting region and are located on the second contact layer.

In one or more of the previous embodiments, the PV device can further include a conducting layer disposed over the insulating layer that extends from a portion of the second contact layer located in the first PV cell to a portion of the first contact layer of the second PV cell exposed by the feature scribe. In some embodiments the conducting layer comprises an interconnecting region and gridlines that are connected to and extend from the interconnecting region and are located on the second contact layer.

In one or more of the previous embodiments, the PV device can further include a conducting layer disposed over the insulating layer that extends from a portion of the second contact layer located in the first PV cell to a portion of the first contact layer of the second PV cell exposed by the feature scribe. In some embodiments a conducting layer disposed over the insulating layer that extends from a portion of the second contact layer located in the first PV cell to a portion of the second contact layer of the second PV cell located outside of the feature scribe, and fills the feature scribe. In some embodiments, an additional scribe line is formed through the second contact layer and the semiconductor layer of the second PV cell.

Embodiments include a photovoltaic (PV) device including a plurality of PV cells coupled in series, wherein the plurality PV cells include a first contact layer, a semiconductor layer disposed over the first contact layer, and a second contact layer disposed over the semiconductor layer, and a feature scribe that extends between a first PV cell and a second PV cell of the plurality of PV cells, the feature scribe exposing at least a portion of the first contact layer of the first PV cell and the second PV cell, a first insulating layer positioned over at least the leading edge of the feature scribe and extends to a portion of the first contact layer of the second PV cell that is exposed by the feature scribe, and a second insulating layer that extends from a portion of the first contact layer located in the second PV cell exposed by the feature scribe to at least a trailing edge of the feature scribe.

In one or more embodiments of the PV device the feature scribe is formed through a portion of the second contact layer and at least a portion of the semiconductor layer of the first PV cell and the second PV cell.

In one or more of the previous embodiments, the PV device can further include a conducting layer disposed over the first insulating layer that extends from a portion of the second contact layer located in the first PV cell and outside of the feature scribe to a portion of the first contact layer of the second PV cell exposed by the feature scribe. In some embodiments, the conducting layer includes a plurality of conducting regions that extend from portions of the second contact layer located in the first PV cell and outside of the feature scribe to portions of the first contact layer of the second PV cell exposed by the feature scribe. In some embodiments, the conducting layer further includes an interconnecting region connected to the plurality of conducting regions and gridlines that are connected to and extend from the interconnecting region and are located above the second contact layer.

In one or more of the previous embodiments, the PV device can further include a conducting layer disposed over the first insulating layer that extends from a portion of the second contact layer located in the first PV cell and outside of the feature scribe to a portion of the first contact layer of the second PV cell exposed by the feature scribe. In some embodiments, the conducting layer includes an interconnecting region and gridlines that are connected to and extend from the interconnecting region and are located above the second contact layer.

Embodiments include a photovoltaic (PV) device including a plurality PV cells coupled in series, wherein the plurality PV cells include a first contact layer, a semiconductor layer disposed over the first contact layer, and a second contact layer disposed over the semiconductor layer, and a feature scribe that extends between a first PV cell and a second PV cell of the plurality of PV cells and exposes a portion of the first contact layer of the first PV cell and the second PV cell, and an insulating layer including a first insulating layer portion that extends from at least a leading edge of the feature scribe to a portion of the first contact layer of the second PV cell located within the feature scribe, a second insulating layer portion that extends from a portion of the first contact layer of the second PV cell located within the feature scribe to at least a trailing edge of the feature scribe, and a feature formed between the first insulating layer portion and the second insulating layer portion that exposes a portion of the first contact layer within the feature scribe.

In one or more of the previous embodiments, the PV device can further include a conducting layer disposed over the first insulating layer portion that extends from a portion of the second contact layer located in the first PV cell and outside of the feature scribe to a portion of the first contact layer of the second PV cell located within the feature scribe. In some embodiments, the conducting layer includes a plurality of conducting regions that extend from portions of the second contact layer located in the first PV cell and outside of the feature scribe to portions of the first contact layer of the second PV cell exposed by the feature scribe. In some embodiments, the conducting layer further includes an interconnecting region connected to the plurality of conducting regions and gridlines that are connected to and extend from the interconnecting region and are located above the second contact layer.

In one or more of the previous embodiments, the PV device can further include a conducting layer disposed over the first insulating layer portion that extends from a portion of the second contact layer located in the first PV cell and outside of the feature scribe to a portion of the first contact layer of the second PV cell located within the feature scribe. In some embodiments, the conducting layer includes an interconnecting region and gridlines that are connected to and extend from the interconnecting region and are located above the second contact layer.

Embodiments include a method including forming a feature scribe that extends from a first PV cell and a second PV cell of a plurality of PV cells, the plurality of PV cells including a first contact layer, a semiconductor layer disposed over the first contact layer, and a second contact layer disposed over the semiconductor layer, and depositing an insulating layer that covers at least a leading edge of the feature scribe and extends to a portion of the first contact layer of the second PV cell that is exposed by the feature scribe.

In one or more of the previous embodiments, the feature scribe is formed through a portion of the second contact layer and a portion of the semiconductor layer of the first PV cell and the second PV cell.

In one or more of the previous embodiments, the feature scribe has a width of about 30 μm to about 300 μm.

In one or more of the previous embodiments, the method further includes depositing a conducting layer over the insulating layer that extends from a portion of the second contact layer located in the first PV cell and outside of the feature scribe to a portion of the first contact layer of the second PV cell exposed by the feature scribe. In some embodiments, the conducting layer comprises a plurality of conducting regions that extend from portions of the second contact layer located in the first PV cell and outside of the feature scribe to portions of the first contact layer of the second PV cell exposed by the feature scribe. In some embodiments, the conducting layer further includes an interconnecting region connected to the plurality of conducting regions and gridlines that are connected to and extend from the interconnecting region and are located above the second contact layer.

In one or more of the previous embodiments, the method further includes depositing a conducting layer over the insulating layer that extends from a portion of the second contact layer located in the first PV cell and outside of the feature scribe to a portion of the first contact layer of the second PV cell exposed by the feature scribe. In some embodiments, the conducting layer includes an interconnecting region and gridlines that are connected to and extend from the interconnecting region and are located above the second contact layer.

In one or more of the previous embodiments, the method further includes depositing a conducting layer over the insulating layer that extends from a portion of the second contact layer located in the first PV cell and outside of the feature scribe to a portion of the first contact layer of the second PV cell exposed by the feature scribe. In some embodiments, the method further includes depositing a conducting layer over the insulating layer that extends from a portion of the second contact layer located in the first PV cell and outside of the feature scribe to a portion of the second contact layer of the second PV cell located outside of the feature scribe, and fills the feature scribe. In some embodiments, an additional scribe line is formed through the second contact layer and the semiconductor layer of the second PV cell.

Embodiments include a method including forming a feature scribe that extends from a first PV cell and a second PV cell of a plurality of PV cells, the plurality of PV cells including a first contact layer a semiconductor layer disposed over the first contact layer, and a second contact layer disposed over the semiconductor layer, depositing a first insulating layer that covers at least a leading edge of the feature scribe and extends to a portion of the first contact layer of the second PV cell that is exposed by the feature scribe, and depositing a second insulating layer that extends from a portion of the first contact layer located in the second PV cell exposed by the feature scribe to at least a trailing edge of the feature scribe.

In one or more of the previous embodiments, the feature scribe is formed through a portion of the second contact layer and a portion of the semiconductor layer of the first PV cell and the second PV cell.

In one or more of the previous embodiments, the feature scribe has a width of about 30 μm to about 300 μm.

In one or more of the previous embodiments, the method further includes depositing a conducting layer over the insulating layer that extends from a portion of the second contact layer located in the first PV cell and outside of the feature scribe to a portion of the first contact layer of the second PV cell exposed by the feature scribe. In some embodiments, the conducting layer comprises a plurality of conducting regions that extend from portions of the second contact layer located in the first PV cell and outside of the feature scribe to portions of the first contact layer of the second PV cell exposed by the feature scribe. In some embodiments, the conducting layer further comprises an interconnecting region connected to the plurality of conducting regions and gridlines that are connected to and extend from the interconnecting region and are located above the second contact layer.

In one or more of the previous embodiments, the method further includes depositing a conducting layer over the insulating layer that extends from a portion of the second contact layer located in the first PV cell and outside of the feature scribe to a portion of the first contact layer of the second PV cell exposed by the feature scribe. In some embodiments, the conducting layer comprises an interconnecting region and gridlines that are connected to and extend from the interconnecting region and are located above the second contact layer.

Embodiments include a method including forming a feature scribe that extends from a first PV cell and a second PV cell of a plurality of PV cells, the plurality of PV cells including a first contact layer, a semiconductor layer disposed over the first contact layer, and a second contact layer disposed over the semiconductor layer, wherein the feature scribe is formed through the second contact layer and the semiconductor layer and exposes the first contact layer, depositing an insulating layer that covers at least a leading edge of the feature scribe, at least a trailing edge of the feature scribe, and fills the feature scribe, and forming a feature within the insulating layer, the feature exposing a portion of the first contact layer within the feature scribe and forming a first insulating layer portion and a second insulating layer portion.

In one or more of the previous embodiments, the method further includes depositing a conducting layer over the first insulating layer portion that extends from a portion of the second contact layer located in the first PV cell and outside of the feature scribe to a portion of the first contact layer of the second PV cell located within the feature scribe. In some embodiments, the conducting layer comprises a plurality of conducting regions that extend from portions of the second contact layer located in the first PV cell and outside of the feature scribe to portions of the first contact layer of the second PV cell exposed by the feature scribe. In some embodiments, the conducting layer further comprises an interconnecting region connected to the plurality of conducting regions and gridlines that are connected to and extend from the interconnecting region and are located above the second contact layer.

In one or more of the previous embodiments, the method further includes depositing a conducting layer over the first insulating layer portion that extends from a portion of the second contact layer located in the first PV cell and outside of the feature scribe to a portion of the first contact layer of the second PV cell located within the feature scribe. In some embodiments, the conducting layer comprises an interconnecting region and gridlines that are connected to and extend from the interconnecting region and are located above the second contact layer.

While the foregoing is directed to embodiments of the present disclosure, other and further embodiments of the disclosure may be devised without departing from the basic scope thereof, and the scope thereof is determined by the claims that follow.

What is claimed is:

1. A photovoltaic (PV) device comprising:
a plurality of PV cells coupled in series, wherein the plurality of PV cells comprise:
a first contact layer;
a semiconductor layer disposed over the first contact layer; and
a second contact layer disposed over the semiconductor layer; and
a feature scribe that extends between a first PV cell and a second PV cell of the plurality of PV cells, the feature scribe exposing at least a portion of the first contact layer of the first PV cell and the second PV cell; and
an insulating layer that covers at least a leading edge of the feature scribe and an exposed portion of the first contact layer of the first PV cell that is exposed in the feature scribe.

2. The PV device of claim 1, wherein the feature scribe is formed through a portion of the second contact layer and at least a portion of the semiconductor layer of the first PV cell and the second PV cell.

3. The PV device of claim 1, wherein the feature scribe has a width of about 30 μm to about 300 μm.

4. The PV device of claim 1, further comprising a conducting layer disposed over the insulating layer that extends from a portion of the second contact layer located in the first PV cell to a portion of the first contact layer of the second PV cell exposed by the feature scribe.

5. The PV device of claim 4, wherein the conducting layer comprises a plurality of conducting regions that extend from portions of the second contact layer located in the first PV cell to portions of the first contact layer of the second PV cell exposed by the feature scribe.

6. The PV device of claim 5, wherein the conducting layer further comprises an interconnecting region connected to the plurality of conducting regions to gridlines that are connected to the interconnecting region and are located on the second contact layer.

7. The PV device of claim 4, wherein the conducting layer comprises an interconnecting region and gridlines that are connected to and extend from the interconnecting region and are located on the second contact layer.

8. The PV device of claim 4, further comprising a conducting layer disposed over the insulating layer that extends from a portion of the second contact layer located in the first PV cell to a portion of the second contact layer of the second PV cell located outside of the feature scribe, and fills the feature scribe.

9. The PV device of claim 8, further comprising an additional scribe line formed through the second contact layer and the semiconductor layer of the second PV cell.

10. A photovoltaic (PV) device comprising:
a plurality of PV cells coupled in series, wherein the plurality PV cells comprise:
a first contact layer;
a semiconductor layer disposed over the first contact layer; and
a second contact layer disposed over the semiconductor layer; and
a feature scribe that extends between a first PV cell and a second PV cell of the plurality of PV cells, the feature scribe exposing at least a portion of the first contact layer of the first PV cell and the second PV cell;
a first insulating layer positioned over at least a leading edge of the feature scribe and extends to a portion of the first contact layer of the second PV cell that is exposed by the feature scribe; and
a second insulating layer that extends from a portion of the first contact layer located in the second PV cell exposed by the feature scribe to at least a trailing edge of the feature scribe.

11. The PV device of claim 10, wherein the feature scribe is formed through a portion of the second contact layer and a portion of the semiconductor layer of the first PV cell and the second PV cell.

12. The PV device of claim 10, further comprising a conducting layer disposed over the first insulating layer that extends from a portion of the second contact layer located in the first PV cell and outside of the feature scribe to a portion of the first contact layer of the second PV cell exposed by the feature scribe.

13. The PV device of claim 12, wherein the conducting layer comprises a plurality of conducting regions that extend from portions of the second contact layer located in the first PV cell and outside of the feature scribe to portions of the first contact layer of the second PV cell exposed by the feature scribe.

14. The PV device of claim 13, wherein the conducting layer further comprises an interconnecting region connected to the plurality of conducting regions and gridlines that are connected to and extend from the interconnecting region and are located above the second contact layer.

15. The PV device of claim 12, wherein the conducting layer comprises an interconnecting region and gridlines that are connected to and extend from the interconnecting region and are located above the second contact layer.

16. A photovoltaic (PV) device comprising:
a plurality of PV cells coupled in series, wherein the plurality of PV cells comprise:
a first contact layer;
a semiconductor layer disposed over the first contact layer; and
a second contact layer disposed over the semiconductor layer; and
a feature scribe that extends between a first PV cell and a second PV cell of the plurality of PV cells and exposes a portion of the first contact layer of the first PV cell and the second PV cell; and
an insulating layer comprising:
a first insulating layer portion that extends from at least a leading edge of the feature scribe to a portion of the first contact layer of the second PV cell located within the feature scribe;
a second insulating layer portion that extends from a portion of the first contact layer of the second PV cell located within the feature scribe to at least a trailing edge of the feature scribe; and
a feature formed between the first insulating layer portion and the second insulating layer portion that exposes a portion of the first contact layer within the feature scribe.

17. The PV device of claim 16, further comprising a conducting layer disposed over the first insulating layer portion that extends from a portion of the second contact layer located in the first PV cell and outside of the feature scribe to a portion of the first contact layer of the second PV cell located within the feature scribe.

18. The PV device of claim 17, wherein the conducting layer comprises a plurality of conducting regions that extend from portions of the second contact layer located in the first PV cell and outside of the feature scribe to portions of the first contact layer of the second PV cell exposed by the feature scribe.

19. The PV device of claim 18, wherein the conducting layer further comprises an interconnecting region connected to the plurality of conducting regions and gridlines that are connected to and extend from the interconnecting region and are located above the second contact layer.

20. The PV device of claim 17, wherein the conducting layer comprises an interconnecting region and gridlines that are connected to and extend from the interconnecting region and are located above the second contact layer.
